(19) United States
(12) Patent Application Publication
(10) Pub. No.: US 2026/0013297 A1
(43) Pub. Date: Jan. 8, 2026

(54) DISPLAY APPARATUS

(71) Applicant: LG Display Co., Ltd., Seoul (KR)

(72) Inventors: TaeYoon KIM, Seoul (KR); HyeSun JUNG, Seoul (KR); BungGoo KIM, Paju-si (KR); HyoungHo AHN, Paju-si (KR); HeeWon LEE, Paju-si (KR); JunYoung JO, Paju-si (KR)

(73) Assignee: LG Display Co., Ltd., Seoul (KR)

(21) Appl. No.: 19/223,403

(22) Filed: May 30, 2025

(30) Foreign Application Priority Data
Jul. 2, 2024 (KR) 10-2024-0087129

(51) Int. Cl. H10H 29/49; H10H 29/37

(52) U.S. Cl. CPC H10H 29/49; H10H 29/37

(57) ABSTRACT

A display device, in one or more examples, may include a substrate, an active area, a non-active area, a pixel driving circuit disposed on the substrate in the active area, a plurality of micro LEDs which is disposed on the pixel driving circuit in the active area and is electrically connected to the pixel driving circuit, a plurality of organic insulating layers disposed on the substrate in each of the active area and the non-active area, and a plurality of first pad electrodes disposed on the plurality of organic insulating layers in the non-active area, wherein a total thickness of the plurality of organic insulating layers in an area overlapping the plurality of first pad electrodes is larger than a total thickness of the plurality of organic insulating layers in an area between the plurality of first pad electrodes.

### CROSS-REFERENCE TO RELATED APPLICATIONS

This application claims the benefit of and priority to Korean Patent Application No. 10-2024-0087129 filed on Jul. 2, 2024, in the Korean Intellectual Property Office, the entire contents of which are incorporated herein by reference for all purposes.

### BACKGROUND

### 1. Technical Field

The present disclosure relates to a display device.

### 2. Description of Related Art

Display devices are being applied to various electronic devices, such as TVs, mobile phones, notebooks, and tablets.

As display devices, there are an organic light emitting display (OLED) which is a self-emitting device and a liquid crystal display (LCD) which requires a separate light source.

Recently, a display device including a light emitting diode (LED) is attracting attention as a next generation display device. The light emitting diode is formed of an inorganic material, rather than an organic material so that lighting speed is faster, a luminous efficiency is excellent, and an image with a higher luminance is displayed, as compared with the liquid crystal display or the organic light emitting display.

The description of related art should not be considered prior art merely because it is mentioned in or associated with this section. The description of related art includes information that describes one or more aspects of the subject technology, and the description in this section does not limit the scope of the invention.

### SUMMARY

An aspect of the present disclosure is to provide a display device which suppresses the clumping of conductive materials disposed between pad electrodes of a flexible circuit board caused when a display panel and the flexible circuit board are bonded.

Further, an aspect of the present disclosure is to provide a display device which suppresses the clumping of conductive materials to suppress a short-circuit between adjacent conductive materials and minimize a burnt defect due to external factors.

Aspects of the present disclosure are not limited to the above-mentioned aspects, and other aspects, which are not mentioned above, can be clearly understood by those skilled in the art from the following descriptions.

A display device according to an aspect of the present disclosure comprises a substrate, an active area, a non-active area, a pixel driving circuit disposed on the substrate in the active area, a plurality of micro LEDs which is disposed on the pixel driving circuit in the active area and is electrically connected to the pixel driving circuit, a plurality of organic insulating layers disposed on the substrate in each of the active area and the non-active area, and a plurality of first pad electrodes disposed on the plurality of organic insulating layers in the non-active area, wherein a total thickness of the plurality of organic insulating layers in an area overlapping the plurality of first pad electrodes is larger than a total thickness of the plurality of organic insulating layers in an area between the plurality of first pad electrodes.

A display device according to as another aspect of the present disclosure comprises a substrate, an active area, a pad area, a pixel driving circuit disposed on the substrate in the active area, a first insulating layer which is disposed on the pixel driving circuit in the active area and is disposed on the substrate in the pad area, a second insulating layer disposed on the first insulating layer in the active area and the pad area, a third insulating layer disposed on the second insulating layer in the active area and the pad area, a plurality of banks disposed on the third insulating layer in the active area, a plurality of micro LEDs disposed on the plurality of banks, a plurality of insulating patterns disposed on the third insulating layer in the pad area, a plurality of first pad electrodes disposed on a plurality of insulating patterns in the pad area; and a plurality of opening areas formed by the plurality of insulating patterns between the plurality of first pad electrodes.

According to one or more aspects of the present disclosure, in the display device, the clumping of conductive materials disposed between pad electrodes of a flexible circuit board caused when a display panel and the flexible circuit board are bonded can be suppressed.

Further, according to one or more aspects of the present disclosure, in the display device, the clumping of conductive materials between the pad electrodes can be suppressed to suppress a short-circuit between the conductive materials and minimize a burnt defect caused thereby.

According to one or more aspects of the present disclosure, in the display device, a defect of a pad unit, in which the pad electrode is disposed, can be suppressed to improve the lifespan of the display device. Accordingly, the display device according to one or more aspects of the present disclosure can be highly efficiently driven at a low power.

The effects according to one or more aspects of the present disclosure are not limited to the descriptions provided above, and other various effects are provided in the present disclosure.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is an exploded perspective view of a display device according to an example embodiment of the present disclosure;

FIG. 2 is a plan view of a display device according to an example embodiment of the present disclosure;

FIG. 3 is an enlarged view of a display device according to an example embodiment of the present disclosure;

FIG. 4 is a view illustrating a circuit structure according to an example embodiment of the present disclosure;

FIG. 5 is a plan view of a display device according to an example embodiment of the present disclosure;

FIG. 6 is a plan view of a display device according to an example embodiment of the present disclosure;

FIG. 7 is a plan view of a display device according to an example embodiment of the present disclosure;

FIG. 8 is a cross-sectional view taken along VIII-VIII′ of FIG. 3;

FIG. 9 is a cross-sectional view of a display device according to an example embodiment of the present disclosure;

FIG. 10 is an enlarged cross-sectional view of a second non-active area of FIG. 8;

FIG. 11 is a cross-sectional view of a display device according to another example embodiment of the present disclosure;

FIG. 12 is an enlarged cross-sectional view of a second non-active area of FIG. 11;

FIG. 13 is an enlarged cross-sectional view of a second non-active area of a display device according to still another example embodiment of the present disclosure; and

FIGS. 14 to 17 are views illustrating devices to which a display device according to example embodiments of the present disclosure is applied.

### DETAILED DESCRIPTION

Advantages and characteristics of the present disclosure and a method of achieving the advantages and characteristics will be clear by referring to example embodiments described below in detail together with the accompanying drawings. However, the present disclosure is not limited to the example embodiments disclosed herein but will be implemented in various forms. The example embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the example embodiments of the present disclosure are merely examples, and the present disclosure is not limited thereto. Like reference numerals generally denote like elements throughout the disclosure. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.”

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When explaining temporal relationships, terms such as “after,” “following,” “subsequent to,” or “before,” etc., may include non-consecutive cases unless terms like “immediately” or “directly” are used.

Terms such as “first,” “second,” etc. are used to describe various components, but these components are not limited by these terms. These terms are merely used to distinguish one component from another. Therefore, a first component mentioned herein could be a second component within the technical scope of the present disclosure.

In describing the components of the present disclosure, terms such as first, second, A, B, (a), or (b) may be used. These terms are only intended to distinguish that one component from other components, and the nature, order, sequence, or number of the respective component is not limited by these terms.

When a component is described as being “connected,” “coupled,” “joined,” or “attached” to another component, it should be understood that the component may be directly connected, coupled, joined, or attached to the other component, but unless explicitly specified otherwise, it may also be indirectly connected, coupled, joined, or attached with another component intervening between each component.

When a component or layer is described as being “in contact with” or “overlapping” another component or layer, the component or layer may directly contact or overlap the other component or layer, but unless explicitly specified otherwise, it should be understood that it may also indirectly contact or overlap with another component intervening between each component.

The term “at least one” should be understood to include all combinations of one or more of the associated components. For example, “at least one of first, second, and third components” means not only the first, second, or third component, but also includes all combinations of two or more components from among the first, second, and third components.

The terms “first direction,” “second direction,” “third direction,” “X-axis direction,” “Y-axis direction,” and “Z-axis direction” should not be interpreted solely as geometric relationships perpendicular to each other, but may indicate broader directionality within the range where the configuration of the present disclosure can function.

The features of various embodiments in the present disclosure may be partially or wholly combined or associated with each other, various technical interlocking and operations are possible, and each embodiment may be implemented independently of each other or may be implemented together in an associated relationship.

Hereinafter, a display apparatus according to example embodiments of the present disclosure will be described in detail with reference to accompanying drawings.

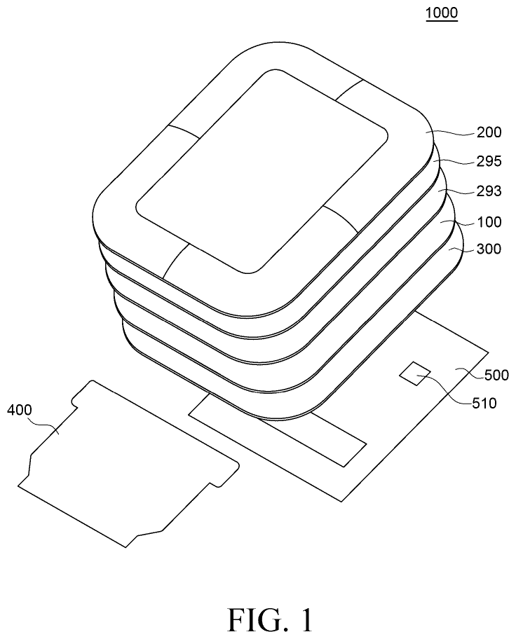

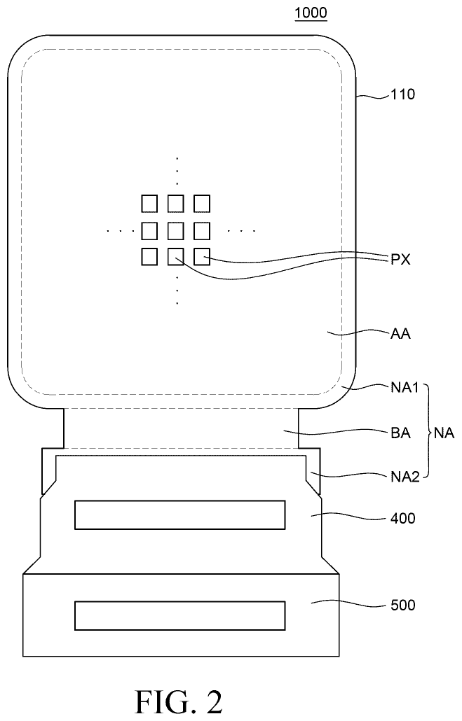

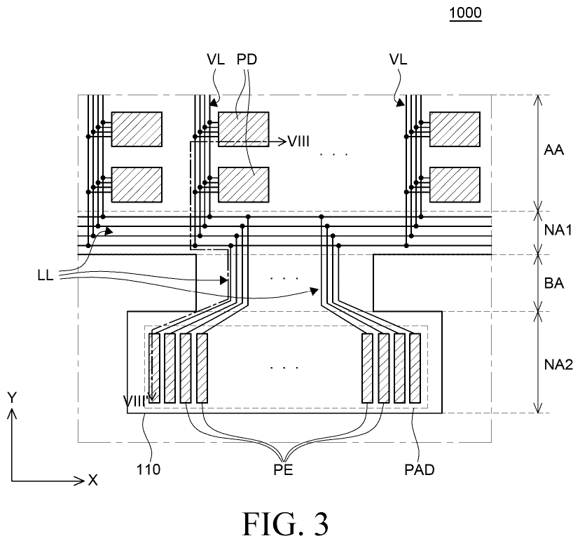

FIG. 1 is a perspective view illustrating a display device according to an example embodiment of the present disclosure. FIG. 2 is a plan view of a display device according to an example embodiment of the present disclosure. FIG. 3 is an enlarged view of a display device according to an example embodiment of the present disclosure.

Referring to FIGS. 1 to 3, a display device 1000 according to an example embodiment of the present disclosure may include a display panel 100, a polarization layer 293, an adhesive layer 295, a cover member 200, a support substrate 300, a flexible circuit board 400, and a printed circuit board 500.

For example, the display panel 100 of the display device 1000 may include a substrate 110. The substrate 110 may be a member which supports other components of the display device 1000. The substrate 110 may be formed of an insulating material. For example, the substrate 110 may be formed of glass or resin. Further, the substrate 110 may also be formed of a material having flexibility. For example, the substrate 110 may be formed of a plastic material having flexibility, such as polyimide (PI), but the example embodiments of the present disclosure are not limited thereto.

The display panel 100 may implement information, videos, and/or images which are provided to users. For example, the display panel 100 may include an active area AA and a non-active area NA. For example, the substrate 110 may include an active area AA and a non-active area NA. However, the active area AA and the non-active area NA are not mentioned to be limited to the substrate 110, but may be mentioned for the entire display device 1000.

The active area AA may be an area where images are displayed. The active area AA may include a plurality of pixels PX. Each of the plurality of pixels PX may be configured by a plurality of sub pixels. A plurality of micro LEDs may be disposed in each of the plurality of sub pixels. Therefore, the display device 1000 according to an example embodiment of the present disclosure may be an inorganic light emitting display device.

The non-active area NA may be an area where no image is displayed. In the non-active area NA, various wiring lines and circuits for driving the plurality of pixels PX of the active area AA may be disposed. For example, in the non-active area NA, various wiring lines and driving circuits may be mounted and a pad unit PAD to which an integrated circuit and a printed circuit are connected may be disposed, but the example embodiments of the present disclosure are not limited thereto.

For example, the driving circuit may be a data driving circuit and/or a gate driving circuit, but the example embodiments of the present disclosure are not limited thereto. Wiring lines through which a control signal for controlling driving circuits is supplied may be disposed. For example, the control signal may include various timing signals including a clock signal, an input data enable signal, and synchronization signals, but the example embodiments of the present disclosure are not limited thereto. The control signal may be received through the pad unit PAD. For example, in the non-active area NA, link lines LL may be disposed to transmit signals. For example, driving components, such as a flexible circuit board 400 and a printed circuit board 500, may be connected to the pad unit PAD.

According to the present specification, the non-active area NA may include a first non-active area NA1, a bending area BA, and a second non-active area NA2 (also referred to as a pad area). For example, the first non-active area NA1 may be an area which encloses at least a part of the active area AA. The bending area BA is an area extending from at least one side, among a plurality of sides of the first non-active area NA1 and may be a bendable area. The second non-active area NA2 is an area extending from the bending area BA and the pad unit PAD is disposed therein. For example, the bending area BA may be in a bent state and the other areas of the substrate 110 excluding the bending area BA may be in a flat state. In this case, as the bending area BA is bent, the second non-active area NA2 may be located on a rear surface of the active area AA, but the example embodiments of the present disclosure are not limited thereto.

The active area AA of the substrate 110 or the display device 1000 may be configured with various shapes depending on a design of the display device 1000. For example, the active area AA may be configured with a rectangular shape formed with four rounded corners, but the example embodiments of the present disclosure are not limited thereto. As another example, the active area AA may be configured with a rectangular shape formed with four right-angled corners or a circular shape, but the example embodiments of the present disclosure are not limited thereto.

According to one or more aspects of the present disclosure, a width of the second non-active area NA2 in which a plurality of pad electrodes PE is disposed may be larger than a width of the bending area BA in which only a plurality of link lines LL is disposed. Further, a width of the active area AA in which the plurality of sub pixels is disposed may be larger than a width of the bending area BA in which only a plurality of link lines LL is disposed. Even though in the drawing, it is illustrated that the width of the bending area BA is smaller than a width of the other area of the substrate 110, the shape of the substrate 110 including the bending area BA is illustrative and the example embodiments of the present disclosure are not limited thereto.

Referring to FIG. 3, a plurality of pixel driving circuits PD may be disposed on the substrate 110 in the active area AA. The plurality of pixel driving circuits PD may be circuits for driving micro LEDs of the plurality of sub pixels. Each of the plurality of pixel driving circuits PD includes a plurality of transistors including a driving transistor and a storage capacitor and supplies a control signal, a power, and a driving current to the micro LEDs of the plurality of sub pixels to control an emission operation of the plurality of micro LEDs. For example, the pixel driving circuit PD may include a power line and a signal line for controlling emission on/off of the micro LED and/or an emission time. For example, the plurality of pixel driving circuits PD may be driving drives manufactured using a metal-oxide-silicon field effect transistor (MOSFET) manufacturing process on a semiconductor substrate, but the example embodiments of the present disclosure are not limited thereto. The driving driver includes a plurality of pixel driving circuits PD and may drive a plurality of sub pixels. A plurality of micro LED ED may be disposed on the pixel driving circuit PD in the active area AA and may be electrically connected to the pixel driving circuit PD.

Referring to FIG. 1 together, the flexible circuit board 400 and the printed circuit board 500 may be disposed below the display panel 100. The flexible circuit board 400 and the printed circuit board 500 may be disposed at least at one edge of the display panel 100, but the example embodiments of the present disclosure are not limited thereto. One side of the flexible circuit board 400 is attached to the display panel 100 and the other side is attached to the printed circuit board 500, but the example embodiments of the present disclosure are not limited thereto. The flexible circuit board 400 may be a flexible film, but the example embodiments of the present disclosure are not limited thereto.

A pad unit PAD including the plurality of first pad electrodes PE1 may be disposed in the second non-active area NA2. In the pad unit PAD, a driving component including one or more flexible circuit boards (or flexible films) 400 and the printed circuit board 500 may be attached or bonded. The plurality of first pad electrodes PE1 of the pad unit PAD is electrically connected to one or more flexible circuit boards (or flexible films) 400 and transmits various signals (or powers) from the printed circuit board 500 and the flexible circuit board (or a flexible film) 400 to the plurality of pixel driving circuits PD of the active area AA.

The flexible circuit board (or flexible film) 400 may be a film on which various components are disposed on a base film having ductility. For example, driving ICs such as a gate driver IC or a data driver IC may be disposed in the flexible circuit board (or flexible film) 400, but the example embodiments of the present disclosure are not limited thereto. The driving IC may be a component which processes data and driving signals to display images. The driving IC may be disposed by a chip on glass (COG), a chip on film (COF), or a tape carrier package (TCP) technique depending on a mounting method, but the example embodiments of the present disclosure are not limited thereto. The flexible circuit board (or flexible film) 400 may be attached or bonded onto the plurality of first pad electrodes PE1 through a conductive adhesive layer, but the example embodiments of the present disclosure are not limited thereto.

The printed circuit board 500 may be a component which is electrically connected to one or more flexible circuit boards (or flexible films) 400 and supplies a signal to the driving IC. The printed circuit board 500 may be disposed at one side of the flexible circuit board (or flexible film) 400 to be electrically connected to the flexible circuit board (or flexible film) 400. On the printed circuit board 500, various components for supplying various signals to the driving IC may be disposed. For example, on the printed circuit board 500, various components, such as a timing controller, a power source, a memory, or a processor, may be disposed. For example, the printed circuit board 500 may include a power management integrated circuit (PMIC), but the example embodiments of the present disclosure are not limited thereto.

The printed circuit board 500 may include at least one hole 510, but the example embodiments of the present disclosure are not limited thereto. An internal component which senses ambient light or temperature to be supplied to a plurality of sensors may be disposed in an area corresponding to at least one hole 510. For example, the internal component may include an ambient light sensor (ALS) or a temperature sensor, but the example embodiments of the present disclosure are not limited thereto. For example, the hole 510 may be a transmission hole, but the example embodiments of the present disclosure are not limited thereto.

Referring to FIG. 1, a polarization layer 293 may be disposed on the display panel 100. The polarization layer 293 may suppress or reduce the influence on the micro LED caused by light generated from an external light source and entering inside the display panel 100.

A cover member 200 may be disposed on the polarization layer 293. The cover member 200 may be a member for protecting the display panel 100. The adhesive layer 295 is disposed between the polarization layer 293 and the cover member 200. The cover member 200 may be attached to the display panel 100 using the adhesive layer 295. The adhesive layer 295 may include an optically clear adhesive (OCA), an optically clear resin (OCR), or a pressure sensitive adhesive (PSA), but the example embodiments of the present disclosure are not limited thereto.

The support substrate 300 may be disposed between the display panel 100 and the printed circuit board 500. The support substrate 300 may reinforce a rigidity of the display panel 100. The support substrate 300 may be a back plate, but the example embodiments of the present disclosure are not limited thereto.

Referring to FIGS. 1 to 3, the plurality of link lines LL may be disposed in the non-active area NA. The plurality of link lines LL may be wiring lines which transmit various signals from one or more flexible circuit boards (or flexible films) 400 and the printed circuit board 500 to the active area AA. The plurality of link lines LL extends from the plurality of first pad electrodes PE1 of the second non-active area NA2 toward the bending area BA and the first non-active area NA1 to be electrically connected to the plurality of driving lines VL of the active area AA. The plurality of pixel driving circuits PD is supplied with signals from one or more flexible circuit boards (or flexible films) 400 and the printed circuit board 500 through the driving line VL of the active area AA and the link line LL of the non-active area NA to be driven.

For example, the plurality of driving lines VL may be wiring lines for transmitting a signal output from the flexible circuit board (or flexible film) 400 and the printed circuit board 500 to the plurality of pixel driving circuits PD together with the plurality of link lines LL. The plurality of driving lines VL is disposed in the active area AA to be electrically connected to each of the plurality of pixel driving circuits PD. The plurality of driving lines VL extends toward the non-active area NA from the active area AA to be electrically connected to the plurality of link lines LL. Accordingly, a signal output from the flexible circuit board (or flexible film) 400 and the printed circuit board 500 may be transmitted to each of the plurality of pixel driving circuits PD through the plurality of link lines LL and the plurality of driving lines VL.

As the bending area BA is bent, a part of the plurality of link lines LL may be bent together. A stress is concentrated in the bent part of the link line LL, which causes a crack on the link line LL. Accordingly, the plurality of link lines LL may be configured by a conductive material having excellent ductility to reduce the crack caused when the bending area BA is bent. For example, the plurality of link lines LL may be configured by a conductive material having excellent ductility, such as gold (Au), silver (Ag), or aluminum (Al), but the example embodiments of the present disclosure are not limited thereto. Further, the plurality of link lines LL may be configured by one of various conductive materials used for the active area AA. For example, the plurality of link lines LL may be configured by molybdenum (Mo), chrome (Cr), titanium (Ti), nickel (Ni), neodymium (Nd), copper (Cu), and an alloy of silver (Ag) and magnesium (Mg) or an alloy thereof, but the example embodiments of the present disclosure are not limited thereto. The plurality of link lines LL may be configured by a multi-layered structure including various conductive materials. For example, the plurality of link lines LL may be configured with a triple layered structure of titanium (Ti)/aluminum (Al)/titanium (Ti), but the example embodiments of the present disclosure are not limited thereto.

The plurality of link lines LL may be configured with various shapes to reduce a stress. At least a part of the plurality of link lines LL disposed on the bending area BA may extend in the same direction as an extending direction of the bending area BA or extend in a different direction from the extending direction of the bending area BA to reduce a stress. For example, when the bending area BA extends in one direction toward the second non-active area NA2 from the first non-active area NA1, at least a part of the link line LL disposed on the bending area BA may extend in an inclined direction from one direction. As another example, at least a part of the plurality of link lines LL may be configured by various shapes of patterns. For example, at least a part of the plurality of link lines LL disposed on the bending area BA may have a shape in which a conductive pattern having at least one shape of a diamond shape, a rhombus shape, a trapezoidal wave shape, a triangular wave shape, a sawtooth wave shape, a sine wave shape, a circular shape, an omega (Ω) shape is repeatedly disposed. However, the example embodiments of the present disclosure are not limited thereto. Accordingly, in order to minimize a stress concentrated on the plurality of link lines LL and a crack caused thereby, a shape of the plurality of link lines LL may be various shapes including the above-mentioned shapes, but the example embodiments of the present disclosure are not limited thereto.

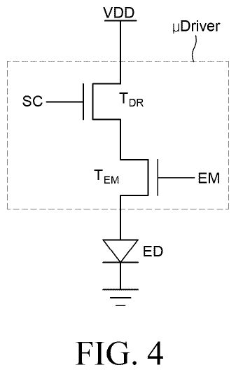

FIG. 4 is a view illustrating a circuit structure according to an example embodiment of the present disclosure.

A pixel driving circuit PD may include a micro driver μDriver. The micro LED ED is electrically connected to the micro driver μDriver of the pixel driving circuit PD to be driven. Even though in FIG. 4, it is illustrated that one micro LED ED is connected to a micro driver μDriver, but the present disclosure is not limited thereto. For example, 8 micro LEDs ED may be connected to one micro driver μDriver. As another example, 16 micro LEDs ED may be connected to one micro driver μDriver or 32 micro LEDs ED or 64 micro LEDs ED may be simultaneously connected to one micro driver μDriver.

One micro driver μDriver may include a driving transistor T_{DR} and an emission transistor T_{EM}, but the example embodiments of the present disclosure are not limited thereto.

For example, a high potential power voltage VDD is applied to a first electrode of the driving transistor T_{DR} and a first electrode of the emission transistor T_{EM} is connected to a second electrode, and a scan signal SC is applied to a gate electrode. The scan signal SC applied to the gate electrode of the driving transistor T_{DR} is a direct current (DC) power and a fixed reference voltage may be applied in every frame, but the example embodiments of the present disclosure are not limited thereto.

The second electrode of the driving transistor T_{DR} is connected to a first electrode of the emission transistor T_{EM}, the micro LED ED is connected to a second electrode, and the emission signal EM is applied to a gate electrode. The emission signal EM applied to the gate electrode of the emission transistor T_{EM} may be a pulse width modulation signal which changes in every frame, but the example embodiments of the present disclosure are not limited thereto.

A first electrode of the micro LED ED is connected to the second electrode of the emission transistor T_{EM} and a second electrode is connected to the ground. For example, the first electrode is an anode electrode and the second electrode is a cathode electrode, but the example embodiments of the present disclosure are not limited thereto.

Each of the driving transistor T_{DR} and the emission transistor T_{EM} may be an n type transistor or a p type transistor.

The driving transistor T_{DR} is turned on by a scan signal SC applied from the timing controller to the micro driver μDriver and the emission transistor T_{EM} is turned on by the emission signal EM. By doing this, the driving current is applied to the micro LED ED via the driving transistor T_{DR} and the emission transistor T_{EM} by the high potential power voltage VDD applied to the first electrode of the driving transistor T_{DR} so that the micro LED ED emits light.

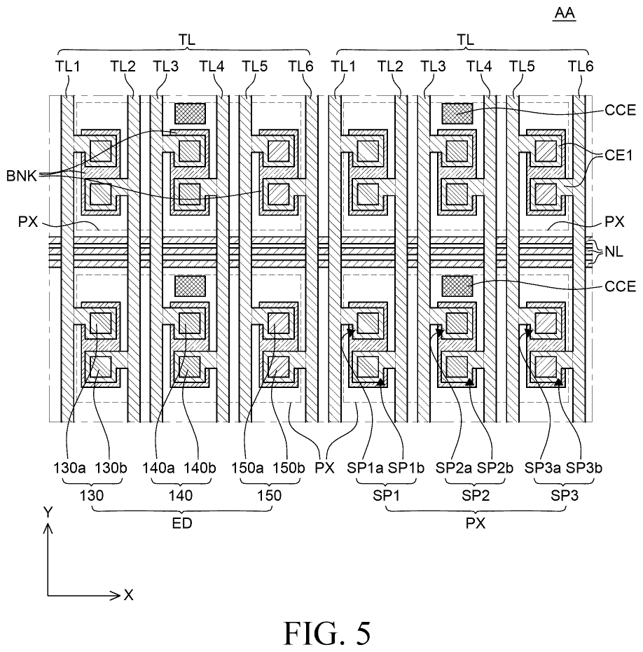

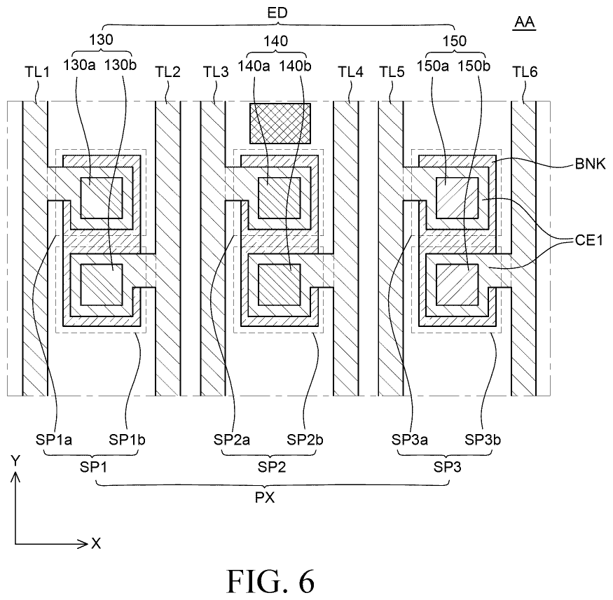

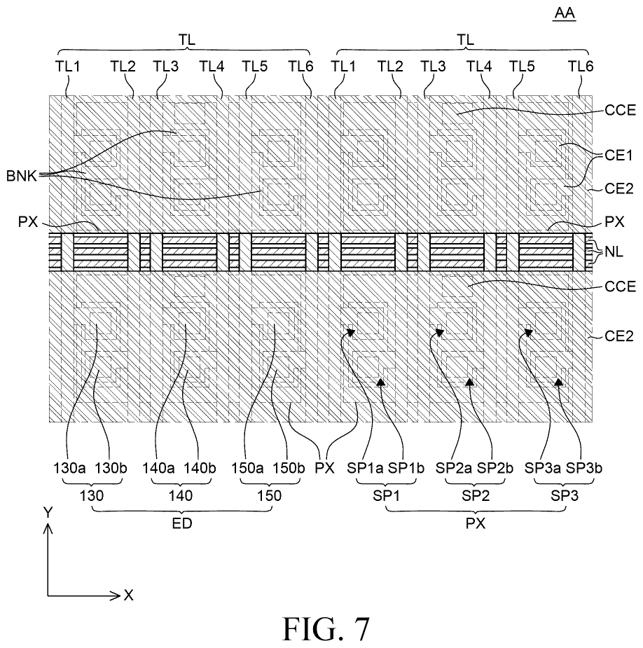

FIGS. 5 to 7 are plan views of a display device according to an example embodiment of the present disclosure. For example, FIG. 5 is an enlarged plan view of an active area including a plurality of pixels. For example, FIG. 6 is an enlarged plan view of an active area including one pixel. For example, FIG. 7 is an enlarged plan view of an active area including a plurality of pixels. In FIGS. 5 and 6, only a plurality of signal lines TL, a plurality of communication lines NL, a plurality of first electrodes CE1, a plurality of banks BNK, and a plurality of micro LEDs (ED) are illustrated, but the example embodiments of the present disclosure are not limited thereto. FIG. 7 is an enlarged plan view in which a plurality of second electrodes CE2 is additionally disposed to FIG. 5.

Referring to FIGS. 5 and 6, a plurality of pixels PX which is configured by a plurality of sub pixels may be disposed in the active area AA. Each of the plurality of sub pixels includes a micro LED ED and independently emits light. The plurality of sub pixels may be disposed in a matrix by forming a plurality of rows and a plurality of columns, but the example embodiments of the present disclosure are not limited thereto.

The plurality of sub pixels may include a first sub pixel SP1, a second sub pixel SP2, and a third sub pixel SP3. For example, any one of the first sub pixel SP1, the second sub pixel SP2, and the third sub pixel SP3 is a red sub pixel, another is a green sub pixel, and the third is a blue sub pixel. The types of the plurality of sub pixels are illustrative, but the example embodiments of the present disclosure are not limited thereto.

Each of the plurality of pixels PX may include one or more first sub pixels SP1, one or more second sub pixels SP2, and one or more third sub pixels SP3. For example, one pixel PX may include one pair of first sub pixels SP1, one pair of second sub pixels SP2, and one pair of third sub pixels SP3. One pair of first sub pixels SP1 may be configured by a 1-1-th sub pixel SPla and a 1-2-th sub pixel SP1b. One pair of second sub pixels SP2 may be configured by a 2-1-th sub pixel SP2a and a 2-2-th sub pixel SP2b. One pair of third sub pixels SP3 may be configured by a 3-1-th sub pixel SP3a and a 3-2-th sub pixel SP3b. For example, one pixel PX may include a 1-1-th sub pixel SPla and a 1-2-th sub pixel SP1b, a 2-1-th sub pixel SP2a and a 2-2-th sub pixel SP2b, and a 3-1-th sub pixel SP3a and a 3-2-th sub pixel SP3b, but the example embodiments of the present disclosure are not limited thereto.

The plurality of sub pixels which forms one pixel PX may be disposed in various ways. For example, in one pixel PX, one pair of first sub pixels SP1 is disposed on the same column, one pair of second sub pixels SP2 is disposed on the same column, and one pair of third sub pixels SP3 is disposed on the same column. The first sub pixels SP1, the second sub pixels SP2, and the third sub pixels SP3 are disposed on the same row. A number and a placement of the plurality of sub pixels which configures one pixel PX are illustrative, but the example embodiments of the present disclosure are not limited thereto.

The plurality of signal lines TL may be disposed in an area between the plurality of sub pixels. The plurality of signal lines TL may extend in a second direction Y between the plurality of sub pixels. The plurality of signal lines TL may be wiring lines which transmit an anode voltage from the pixel driving circuit PD to the plurality of sub pixels. For example, the plurality of signal lines TL may be electrically connected to the plurality of pixel driving circuits PD and the first electrodes CE1 of the plurality of sub pixels. The anode voltage output from the pixel driving circuit PD may be transmitted to the first electrode CE1 of the plurality of sub pixels through the plurality of signal lines TL. For example, the first electrode CE1 may be an electrode which is electrically connected to the anode electrode 134 of the micro LED ED. Therefore, the anode voltage from the signal line TL may be transmitted to the anode electrode 134 of the micro LED ED through the first electrode CE1.

Accordingly, instead of the plurality of transistors and storage capacitors formed in each of the plurality of sub pixels, a pixel driving circuit PD in which a plurality of pixel circuits is integrated is used to simplify the structure of the display device 1000. Further, a circuit which is disposed in each of the plurality of sub pixels is integrated in one pixel driving circuit PD so that highly efficient low power driving is possible.

The plurality of signal lines TL may include a first signal line TL1, a second signal line TL2, a third signal line TL3, a fourth signal line TL4, a fifth signal line TL5, and a sixth signal line TL6. The first signal line TL1 and the second signal line TL2 may be electrically connected to one pair of first sub pixels SP1, respectively. The third signal line TL3 and the fourth signal line TL4 may be electrically connected to one pair of second sub pixels SP2, respectively. The fifth signal line TL5 and the sixth signal line TL6 may be electrically connected to one pair of third sub pixels SP3, respectively.

The first signal line TL1 may be disposed on one of one pair of first sub pixels SP1 and the second signal line TL2 may be disposed on the other one of one pair of first sub pixels SP1. The first signal line TL1 may be electrically connected to one first sub pixel SP1, between one pair of first sub pixels SP1, for example, to the first electrode CE1 of the 1-1-th sub pixel SPla. The second signal line TL2 may be electrically connected to the other first sub pixel SP1, between one pair of first sub pixels SP1, for example, to the first electrode CE1 of the 1-2-th sub pixel SP1b.

The third signal line TL3 may be disposed on one of one pair of second sub pixels SP2 and the fourth signal line TL4 may be disposed on the other one of one pair of second sub pixels SP2. For example, the third signal line TL3 may be disposed to be adjacent to the second signal line TL2. The third signal line TL3 may be electrically connected to one second sub pixel SP2, between one pair of second sub pixels SP2, for example, to the first electrode CE1 of the 2-1-th sub pixel SP2a. The fourth signal line TL4 may be electrically connected to the other second sub pixel SP2, between one pair of second sub pixels SP2, for example, to the first electrode CE1 of the 2-2-th sub pixel SP2b.

The fifth signal line TL5 may be disposed on one of one pair of third sub pixels SP3 and the sixth signal line TL6 may be disposed on the other one of one pair of third sub pixels SP3. For example, the fifth signal line TL5 may be disposed to be adjacent to the fourth signal line TL4. The sixth signal line TL6 may be disposed to be adjacent to the first signal line TL1 connected to the adjacent pixel PX. The fifth signal line TL5 may be electrically connected to one third sub pixel SP3, between one pair of third sub pixels SP3, for example, to the first electrode CE1 of the 3-1-th sub pixel SP3a. The sixth signal line TL6 may be electrically connected to the other third sub pixel SP3, between one pair of third sub pixels SP3, for example, to the first electrode CE1 of the 3-2-th sub pixel SP3b.

The plurality of signal lines TL may be formed of a conductive material. For example, the plurality of signal lines TL may be configured by a conductive material, such as titanium (Ti), aluminum (Al), copper (Cu), molybdenum (Mo), nickel (Ni), chrome (Cr), indium tin oxide (ITO), indium zinc oxide (IZO), indium gallium zinc oxide (IGZO). However, the example embodiments of the present disclosure are not limited thereto. As another example, the plurality of signal lines TL may be formed with a multi-layered structure of conductive materials. For example, the plurality of signal lines TL may be formed with a multi-layered structure of titanium (Ti)/aluminum (Al)/titanium (Ti)/indium tin oxide (ITO), but the example embodiments of the present disclosure are not limited thereto.

A plurality of communication lines NL may be disposed in an area between the plurality of pixels PX. The plurality of communication lines NL may be disposed to extend in the first direction X in an area between the plurality of pixels PX. The plurality of communication lines NL is disposed in the area between the plurality of second electrodes CE2 and does not overlap the plurality of second electrodes CE2. For example, the plurality of communication lines NL may be wiring lines used for short distance communication, such as near field communication (NFC). The plurality of communication lines NL may serve as antennas. For example, the plurality of communication lines NL may be a plurality of connection lines, but the example embodiments of the present disclosure are not limited thereto.

According to one or more aspects of the present disclosure, a bank BNK may be disposed in each of the plurality of sub pixels. The plurality of banks BNK may be structures in which the plurality of micro LEDs (ED) is seated. The plurality of banks BNK may guide a position of the plurality of micro LEDs (ED) during a transfer process of transferring the plurality of micro LEDs ED to the display device 1000. The plurality of micro LEDs ED may be transferred onto the plurality of banks BNK in the transfer process of the plurality of micro LEDs ED. The plurality of banks BNK may be a bank pattern or structure, but the example embodiments of the present disclosure are not limited thereto.

A bank BNK of the first sub pixel SP1, a bank BNK of the second sub pixel SP2, and a bank BNK of the third sub pixel SP3 may be disposed to be spaced apart from each other. The bank BNK of the first sub pixel SP1, the bank BNK of the second sub pixel SP2, and the bank BNK of the third sub pixel SP3 may be configured to be separated from each other. Therefore, the banks BNK of the first sub pixel SP1, the second sub pixel SP2, and the third sub pixel SP3 to which different types of micro LEDs ED are transferred may be easily identified.

The bank BNK of the 1-1-th sub pixel SPla and the bank BNK of the 1-2-th sub pixel SP1b may be connected to each other or spaced apart or separated from each other. For example, in consideration of a design, such as a transfer process requirement, the bank BNK of the 1-1-th sub pixel SPla and the bank BNK of the 1-2-th sub pixel SP1b in which the same type of micro LED ED is disposed may be connected to each other or spaced apart or separated from each other. The bank BNK of the 2-1-th sub pixel SP2a and the bank BNK of the 2-2-th sub pixel SP2b may be connected to each other, spaced apart or separated from each other. The bank BNK of the 3-1-th sub pixel SP3a and the bank BNK of the 3-2-th sub pixel SP3b may be connected to each other, spaced apart or separated from each other. Accordingly, the banks BNK of one pair of first sub pixels SP1, the banks BNK of one pair of second sub pixels SP2, and the banks BNK of one pair of third sub pixels SP3 may be formed in various forms, but the example embodiments of the present disclosure are not limited thereto.

For example, the plurality of banks BNK may be formed of an organic insulating material. The plurality of banks BNK may be configured by a single layer or a double layer of an organic insulating material. For example, the plurality of banks BNK may be configured by a photo resist, polyimide (PI), or acrylic-based material, but the example embodiments of the present disclosure are not limited thereto.

The first electrode CE1 may be disposed in each of the plurality of sub pixels. The first electrode CE1 may be disposed on the bank BNK. The first electrode CE1 may be electrically connected to one signal line TL, among the plurality of signal lines TL. At least a part of the first electrode CE1 extends to the outside of the bank BNK to be electrically connected to the signal line TL which is the most adjacent to the first electrode CE1. For example, a part of the first electrode CE1 of the 1-1-th sub pixel SPla extends to one area of the 1-1-th sub pixel SPla to be electrically connected to the first signal line TL1. A part of the first electrode CE1 of the 1-2-th sub pixel SP1b extends to the other area of the 1-2-th sub pixel SP1b to be electrically connected to the second signal line TL2. A part of the first electrode CE1 of the 2-1-th sub pixel SP2a extends to one area of the 2-1-th sub pixel SP2a to be electrically connected to the third signal line TL3. A part of the first electrode CE1 of the 2-2-th sub pixel SP2b extends to the other area of the 2-2-th sub pixel SP2b to be electrically connected to the fourth signal line TL4. A part of the first electrode CE1 of the 3-1-th sub pixel SP3a extends to one area of the 3-1-th sub pixel SP3a to be electrically connected to the fifth signal line TL5. A part of the first electrode CE1 of the 3-2-th sub pixel SP3b extends to the other area of the 3-2-th sub pixel SP3b to be electrically connected to the sixth signal line TL6.

The first electrode CE1 may be disposed below the plurality of micro LEDs ED to electrically connect the pixel driving circuit PD to the anode electrode 134 of the micro LED ED and transmits an anode voltage from the pixel driving circuit PD to the micro LED ED through the signal line TL. Different voltages may be applied to the first electrodes CE1 of the plurality of sub pixels depending on the image to be displayed. For example, different voltages may be applied to the first electrodes CE1 of the plurality of sub pixels. Therefore, the first electrode CE1 may be a pixel electrode, but the example embodiments of the present disclosure are not limited thereto.

The first electrode CE1 may be configured by a conductive material. For example, the first electrode CE1 may be integrally configured with the plurality of signal lines TL. For example, the first electrode CE1 may be configured by the same conductive material as the plurality of signal lines TL, but the example embodiments of the present disclosure are not limited thereto. For example, the first electrode CE1 may be configured by a conductive material, such as titanium (Ti), aluminum (Al), copper (Cu), molybdenum (Mo), nickel (Ni), chrome (Cr), indium tin oxide (ITO), indium zinc oxide (IZO), and indium gallium zinc oxide (IGZO). However, the example embodiments of the present disclosure are not limited thereto. As another example, the first electrode CE1 may be configured by a multi-layered structure of conductive materials. For example, the plurality of first electrodes CE1 may be configured by a multi-layered structure of titanium (Ti)/aluminum (Al)/titanium (Ti)/indium tin oxide (ITO), but the example embodiments of the present disclosure are not limited thereto.

The micro LED ED may be disposed in each of the plurality of sub pixels. The plurality of micro LEDs (ED) may be disposed on the bank BNK and the first electrode CE1. The plurality of micro LEDs (ED) may be disposed on the first electrode CE1 and may be electrically connected to the first electrode CE1. Accordingly, the micro LED ED may be applied with an anode voltage from the pixel driving circuit PD through the signal line TL and the first electrode CE1 to emit light.

The plurality of micro LEDs (ED) may include a first micro LED 130, a second micro LED 140, and a third micro LED 150. The first micro LED 130 may be disposed in the first sub pixel SP1. The second micro LED 140 may be disposed in the second sub pixel SP2. The third micro LED 150 may be disposed in the third sub pixel SP3. For example, any one of the first micro LED 130, the second micro LED 140, and the third micro LED 150 is a red micro LED, another is a green micro LED, and the third is a blue micro LED, but the example embodiments of the present disclosure are not limited thereto. Therefore, red light, green light, and blue light emitted from the plurality of micro LEDs (ED) are combined to implement various color light including white. The types of the plurality of micro LEDs (ED) are illustrative, but the example embodiments of the present disclosure are not limited thereto.

The first micro LED 130 may include a 1-1-th micro LED 130a disposed in the 1-1-th sub pixel SP1a and a 1-2-th micro LED 130b disposed in the 1-2-th sub pixel SP1b. The second micro LED 140 may include a 2-1-th micro LED 140a disposed in the 2-1-th sub pixel SP2a and a 2-2-th micro LED 140b disposed in the 2-2-th sub pixel SP2b. The third micro LED 150 may include a 3-1-th micro LED 150a disposed in the 3-1-th sub pixel SP3a and a 3-2-th micro LED 150b disposed in the 3-2-th sub pixel SP3b.

Referring to FIGS. 5, 6 and 7 together, the second electrode CE2 may be disposed in each of the plurality of sub pixels. The second electrode CE2 may be disposed on the micro LED ED. The second electrode CE2 may be electrically connected to the pixel driving circuit PD through the plurality of contact electrodes CCE.

For example, the second electrode CE2 may be electrically connected to the cathode electrode 135 of the micro LED ED to transmit a cathode voltage from the pixel driving circuit PD to the micro LED ED. The same cathode voltage may be applied to the second electrodes CE2 of the plurality of sub pixels. For example, the same voltage may be applied to the second electrode CE2 of each of the plurality of sub pixels and the cathode electrode 135 of the micro LED ED. Therefore, the second electrode CE2 may be a common electrode, but the example embodiments of the present disclosure are not limited thereto.

At least a part of the plurality of sub pixel may share the second electrode CE2. At least some of the second electrodes CE2 of the plurality of sub pixels may be electrically connected to each other. As the same voltage is applied to the second electrode CE2, the second electrodes CE2 of at least some of sub pixels are shared. For example, the second electrodes CE2 of at least some pixels PX, among the plurality of pixels PX disposed on the same row, may be connected to each other. For example, one second electrode CE2 may be disposed in the plurality of pixels PX. One second electrode CE2 may be disposed in every n sub pixels.

For example, some of the second electrodes CE2 of the plurality of sub pixels may be spaced apart or separated from each other. For example, a second electrode CE2 connected to pixels PX in a n-th row and a second electrode CE2 connected to pixels PX in a n+1-th row may be spaced apart or separated from each other. For example, the plurality of second electrodes CE2 may be spaced apart from each other with the plurality of communication lines NL extending in the first direction X therebetween. Accordingly, the number of the plurality of sub pixels may be larger than the number of the plurality of second electrodes CE2. As another example, all the second electrodes CE2 of the plurality of sub pixels are connected to each other so that only one second electrode CE2 is disposed on the substrate 110, but the example embodiments of the present disclosure are not limited thereto.

The plurality of second electrodes CE2 may be configured by a transparent conductive material, but the example embodiments of the present disclosure are not limited thereto. The plurality of second electrodes CE2 may be configured by a transparent conductive material so that light emitted from the micro LED ED travels toward the top of the second electrode CE2. For example, the second electrode CE2 may be configured by a transparent conductive material, such as indium tin oxide (ITO), indium zinc oxide (IZO), and indium gallium zinc oxide (IGZO), but the example embodiments of the present disclosure are not limited thereto.

A plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap a plurality of contact electrodes CCE.

For example, the plurality of contact electrodes CCE may be electrically connected to the plurality of second electrodes CE2. The plurality of contact electrodes CCE may be disposed between the substrate 110 and the plurality of second electrodes CE2 to transmit a cathode voltage from the pixel driving circuit PD to the second electrode CE2.

For example, the plurality of micro LEDs is formed on the wafer and the micro LED is transferred onto the substrate 110 of the display device 1000 to manufacture the display device 1000. However, during the process of transferring the plurality of micro LEDs (ED) having a micro size from the wafer to the substrate 110, various defects may be caused. For example, in some sub pixels, a non-transfer defect in which the micro LED is not transferred may occur and in the other sub pixels, a defect that the micro LED ED is transferred in a wrong position may occur due to the alignment error. Further, even though the transfer process is normally performed, the transferred micro LED ED may be defective. Accordingly, in consideration of the defects during the transfer process of the plurality of micro LEDs (ED), a plurality of same type micro LEDs may be transferred in one sub pixel. A lighting test for the plurality of micro LEDs (ED) is performed and only one micro LED ED which is finally determined to be normal may be used.

For example, the 1-1-th micro LED 130a and the 1-2-th micro LED 130b are transferred to one sub pixel together and whether they are defective is tested. If both the 1-1-th micro LED 130a and the 1-2-th micro LED 130b are determined to be normal, only the 1-1-th micro LED 130a is used, but the 1-2-th micro LED 130b is not used. As another example, if only the 1-2-th micro LED 130b between the 1-1-th micro LED 130a and the 1-2-th micro LED 130b is determined to be normal, the 1-1-th micro LED 130a is not used, but only the 1-2-th micro LED 130b is used. Accordingly, even though the plurality of same type micro LEDs (ED) is transferred to one sub pixel, finally, only one micro LED ED is used.

Therefore, any one of one pair of micro LEDs (ED) is a main (or primary) micro LED ED and the other micro LED ED is a redundancy micro LED ED. The redundancy micro LED ED may be an extra micro LED ED which is transferred to prepare for a defect of the main micro LED (ED). When the main micro LED ED is defective, the redundancy micro LED ED may be used instead. Accordingly, the main micro LED ED and the redundancy micro LED ED are transferred together to one sub pixel so that the degradation of the display quality due to the defects of the main micro LED ED and the redundancy micro LED ED may be minimized.

For example, a 1-1-th micro LED 130a, a 2-1-th micro LED 140a, and a 3-1-th micro LED 150a which are transferred into one pixel PX are used as main micro LEDs ED and a 1-2-th micro LED 130b, a 2-2-th micro LED 140b, and a 3-2-th micro LED 150b are used as redundancy micro LEDs ED.

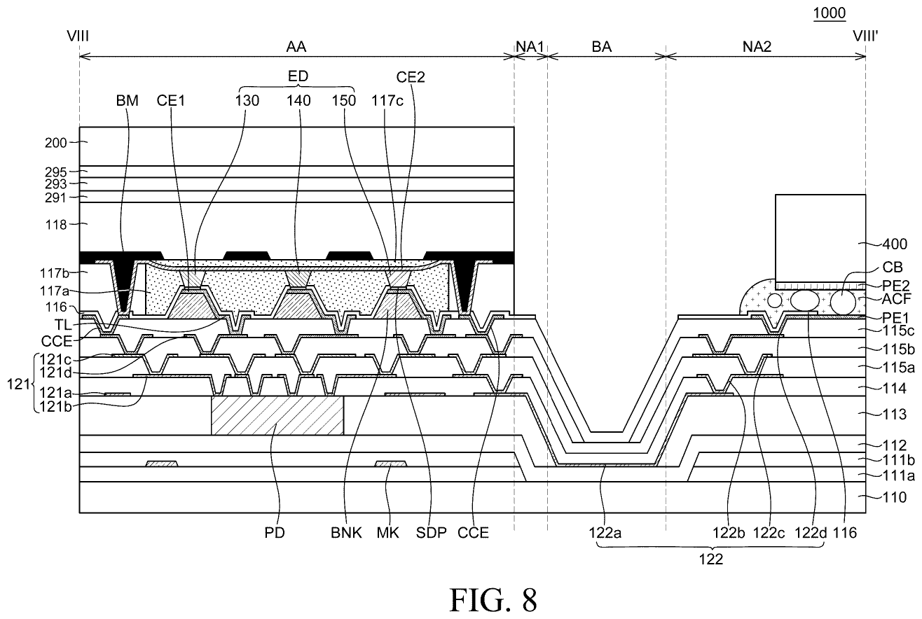

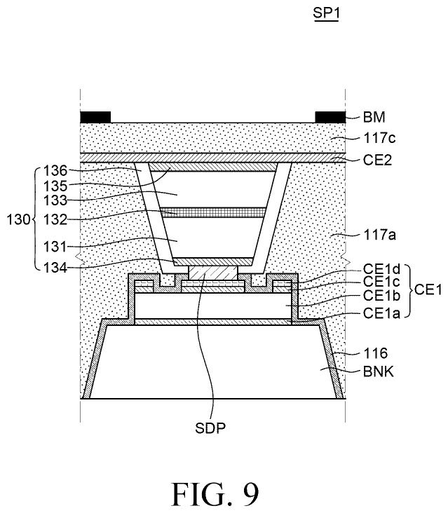

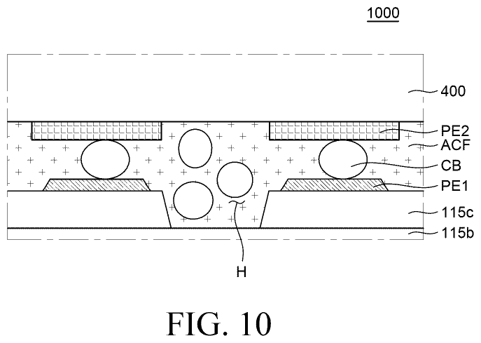

FIG. 8 is a cross-sectional view of a display device according to an example embodiment of the present disclosure. FIG. 9 is a cross-sectional view of a display device according to an example embodiment of the present disclosure. FIG. 10 is an enlarged cross-sectional view of a display device according to an example embodiment of the present disclosure. For example, FIG. 8 is a cross-sectional view of an active area AA, a first non-active area NA1, a bending area BA, and a second non-active area NA2. For example, FIG. 9 is an enlarged cross-sectional view of a first sub pixel. For example, FIG. 10 is an enlarged cross-sectional view of a partial area of the second non-active area NA2.

Referring to FIG. 8, a first buffer layer 111a and a second buffer layer 111b may be disposed in the remaining area of the substrate 110 excluding the bending area BA.

The first buffer layer 111a and the second buffer layer 111b may be disposed in the active area AA, the first non-active area NA1, and the second non-active area NA2. The first buffer layer 111a and the second buffer layer 111b may reduce permeation of moisture or impurities through the substrate 110. The first buffer layer 111a and the second buffer layer 111b may be formed of an inorganic insulating material. For example, the first buffer layer 111a and the second buffer layer 111b may be configured by a single layer or multiple layers of silicon oxide (SiOx) or silicon nitride (SiNx), but the example embodiments of the present disclosure are not limited thereto.

For example, the first buffer layer 111a and the second buffer layer 111b on the bending area BA may be partially removed. A top surface of the substrate 110 located in the bending area BA may be exposed from the first buffer layer 111a and the second buffer layer 111b. The first buffer layer 111a and the second buffer layer 111b which are formed of an inorganic insulating material are removed from the bending area BA to minimize cracks of the first buffer layer 111a and the second buffer layer 111b which may be generated during the bending.

A plurality of alignment keys MK may be disposed between the first buffer layer 111a and the second buffer layer 111b. The plurality of alignment keys MK may be configured to identify a position of the pixel driving circuit PD during the manufacturing process of the display device 1000. For example, the plurality of alignment keys MK may be configured to align a position of the pixel driving circuit PD which is transferred onto the adhesive layer 112. As another example, the plurality of alignment keys MK may be omitted.

The adhesive layer 112 may be disposed on the second buffer layer 111b. The adhesive layer 112 may be disposed in the active area AA, the first non-active area NA1, the bending area BA, and the second non-active area NA2. As another example, in the non-active area NA including the bending area BA, at least a part of the adhesive layer 112 may be removed. For example, the adhesive layer 112 may be formed of any one of adhesive polymer, epoxy resin, UV curable resin, polyimide based, acrylate based, urethane based, and polydimethylsiloxane (PDMS), but the example embodiments of the present disclosure are not limited thereto.

The pixel driving circuit PD may be disposed on the adhesive layer 112 in the active area AA. When the pixel driving circuit PD is implemented as a driving driver, the driving driver may be mounted on the adhesive layer 112 by the transfer process, but the example embodiments of the present disclosure are not limited thereto.

A first protection layer 113 may be disposed on the adhesive layer 112 and the pixel driving circuit PD. The first protection layer 113 may be disposed so as to enclose a side surface of the pixel driving circuit PD, but the example embodiments of the present disclosure are not limited thereto. For example, the first protection layer 113 may be disposed so as to cover at least a part of a top surface of the pixel driving circuit PD. For example, in the bending area BA, the first protection layer 113 may be omitted, but the example embodiments of the present disclosure are not limited thereto. For example, the first protection layer 113 may be partially disposed in the active area AA, the first non-active area NA1, and the second non-active area NA2.

A plurality of first protection layers 113 may be provided. For example, when the plurality of first protection layers 113 is provided, at least one may be entirely disposed in the active area AA, the bending area BA, and the non-active areas NA1 and NA2. The other one may be partially disposed in the active area AA, the first non-active area NA1, and the second non-active area NA2, but the example embodiments of the present disclosure are not limited thereto.

The first protection layer 113 may be configured by an organic insulating material, but the example embodiments of the present disclosure are not limited thereto. For example, the first protection layer 113 may be configured by a photo resist, polyimide (PI), or photo acrylic-based material, but the example embodiments of the present disclosure are not limited thereto. For example, the first protection layer 113 may be an over coating layer or an insulating layer, but the example embodiments of the present disclosure are not limited thereto.

According to the present specification, in the active area AA, the plurality of first connection lines 121 may be disposed on the first protection layer 113. The plurality of first connection lines 121 may be wiring lines which electrically connect the pixel driving circuit PD to the other component. For example, the pixel driving circuit PD may be electrically connected to the plurality of signal lines TL and the plurality of contact electrodes CCE through the plurality of first connection lines 121. For example, the plurality of first connection lines 121 may include a 1-1-th connection line 121a, a 1-2-th connection line 121b, a 1-3-th connection line 121c, and a 1-4-th connection line 121d, but the example embodiments of the present disclosure are not limited thereto.

For example, the plurality of 1-1-th connection lines 121a may be disposed on the first protection layer 113. The plurality of 1-1-th connection lines 121a may be electrically connected to the pixel driving circuit PD. The plurality of 1-1-th connection lines 121a may transmit a voltage output from the pixel driving circuit PD to the first electrode CE1 or the second electrode CE2.

For example, the second protection layer 114 may be disposed on the first protection layer 113. The second protection layer 114 may be entirely disposed in the active area AA and the non-active area NA. In the first non-active area NA1 and the second non-active area NA2, the second protection layer 114 may cover a side surface and a top surface of the first protection layer 113.

The second protection layer 114 may be configured by an organic insulating material. For example, the second protection layer 114 may be configured by a photo resist, polyimide (PI), or photo acrylic-based material, but the example embodiments of the present disclosure are not limited thereto. For example, the first protection layer 113 and the second protection layer 114 may be configured by the same material, but the example embodiments of the present disclosure are not limited thereto.

The plurality of 1-2-th connection lines 121b may be disposed on the second protection layer 114. The plurality of 1-2-th connection lines 121b may be indirectly or directly connected to the pixel driving circuit PD. For example, a part of the 1-2-th connection line 121b may be directly connected to the pixel driving circuit PD through a contact hole of the second protection layer 114. The other part of the 1-2-th connection line 121b may be electrically connected to the 1-1-th connection line 121a through the contact hole of the second protection layer 114, but the example embodiments of the present disclosure are not limited thereto. A voltage output from the pixel driving circuit PD may be transmitted to the first electrode CE1 or the second electrode CE2 through a connection line other than the plurality of 1-2-th connection lines 121b.

A plurality of organic insulating layers may be disposed on the substrate 110 in each of the active area AA and the non-active area NA and may be disposed on the plurality of 1-2-th connection lines 121b. For example, the plurality of organic insulating layers may include a first insulating layer 115a, a second insulating layer 115b, and a third insulating layer 115c. A plurality of first pad electrodes PE1 may be disposed on the plurality of organic insulating layers in the non-active area NA. At least one of the plurality of organic insulating layers may extend between the pixel driving circuit PD and the plurality of micro LEDs ED in the active area AA. A top layer of the plurality of organic insulating layers in the active area AA and a top layer of the plurality of organic insulating layers in the non-active area NA may be disposed on the same layer and, in the non-active area NA, the first pad electrode PE1 may be disposed so as to be in contact with the top layer of the organic insulating layers. The top layer of the plurality of organic insulating layers in the non-active area NA and the top layer of the plurality of organic insulating layers in the active area AA may be connected to each other and are formed of the same material.

The first insulating layer 115a may be disposed on the pixel driving circuit PD in the active area AA and may be disposed on the substrate 110 in the second non-active area NA2 (or the pad area). The first insulating layer 115a may be disposed on the plurality of 1-2-th connection lines 121b. The first insulating layer 115a may be entirely disposed in the active area AA and the non-active area NA, but the example embodiments of the present disclosure are not limited thereto. The first insulating layer 115a may be configured by an organic insulating material, but the example embodiments of the present disclosure are not limited thereto. For example, the first insulating layer 115a may be configured by a photo resist, polyimide (PI), or photo acrylic-based material, but the example embodiments of the present disclosure are not limited thereto.

The plurality of 1-3-th connection lines 121c may be disposed on the first insulating layer 115a. The plurality of 1-3-th connection lines 121c may be electrically connected to the plurality of 1-2-th connection lines 121b. For example, the 1-3-th connection lines 121c may be electrically connected to the 1-2-th connection line 121b through a contact hole of the first insulating layer 115a.

The second insulating layer 115b may be disposed on the plurality of 1-3-th connection lines 121c. The second insulating layer 115b may be disposed in at least a part of the non-active area NA, but the example embodiments of the present disclosure are not limited thereto. For example, the second insulating layer 115b may be disposed in the active area AA, the first non-active area NA1, and the second non-active area NA2, and may be disposed in at least a part of the bending area BA, but the example embodiments of the present disclosure are not limited thereto. For example, the second insulating layer 115b may be disposed on the first insulating layer 115a in the active area AA and the second non-active area NA2 (or the pad area). For example, a part of the second insulating layer 115b disposed in the bending area BA may be removed. Therefore, in the bending area BA, a top surface of the first insulating layer 115a may be exposed by the second insulating layer 115b, but the example embodiments of the present disclosure are not limited thereto. In the non-active area NA, the second insulating layer 115b may be disposed so as to cover the side surface of the first insulating layer 115a, but the example embodiments of the present disclosure are not limited thereto. The second insulating layer 115b may be configured by an organic insulating material, but the example embodiments of the present disclosure are not limited thereto. For example, the second insulating layer 115b may be configured by a photo resist, polyimide (PI), or photo acrylic-based material, but the example embodiments of the present disclosure are not limited thereto.

The plurality of 1-4-th connection lines 121d may be disposed on the second insulating layer 115b. The plurality of 1-4-th connection lines 121d may be electrically connected to the plurality of 1-3-th connection lines 121c. For example, the 1-4-th connection lines 121d may be electrically connected to the 1-3-th connection line 121c through a contact hole of the second insulating layer 115b.

According to one or more aspects of the present disclosure, in the non-active area NA, the plurality of second connection lines 122 may be disposed on the first protection layer 113. The plurality of second connection lines 122 may be wiring lines which transmit a signal transmitted from the flexible circuit board (or flexible film) 400 and the printed circuit board 500 (see FIG. 1) to the pad unit PAD to the pixel driving circuit PD of the active area AA. For example, the plurality of second connection lines 122 is electrically connected to the plurality of first pad electrodes PE1 to be applied with a signal from the flexible circuit board (or flexible film) 400 and the printed circuit board 500.

For example, the plurality of second connection lines 122 extends toward the active area AA from the pad unit PAD to transmit a signal to the wiring line of the active area AA. In this case, the plurality of second connection lines 122 may serve as a link line LL. The plurality of second connection lines 122 may include a 2-1-th connection line 122a, a 2-2-th connection line 122b, a 2-3-th connection line 122c, and a 2-4-th connection line 122d.

The plurality of 2-1-th connection lines 122a may be disposed on the first protection layer 113. The plurality of 2-1-th connection lines 122a may extend from the second non-active area NA2 to the bending area BA and the first non-active area NA1. The plurality of 2-1-th connection lines 122a may transmit a signal transmitted from the flexible circuit board (or flexible film) 400 and the printed circuit board 500 to the pad unit PAD to the pixel driving circuit PD of the active area AA. For example, the plurality of 2-1-th connection lines 122a may be disposed on the same layer as the plurality of 1-1-th connection lines 121a. For example, the plurality of 2-1-th connection lines 122a may be formed of the same material as the plurality of 1-1-th connection lines 121a.

The plurality of 2-2-th connection lines 122b may be disposed on the second protection layer 114. The plurality of 2-2-th connection lines 122b may be disposed in the second non-active area NA2. The 2-2-th connection line 122b may be electrically connected to the 2-1-th connection line 122a through the contact hole of the second protection layer 114. Accordingly, a signal from the flexible circuit board (or flexible film) 400 and the printed circuit board 500 may be transmitted to the 2-1-th connection line 122a through the 2-2-th connection line 122b. For example, the plurality of 2-2-th connection lines 122b may be disposed on the same layer as the plurality of 1-2-th connection lines 121b. For example, the plurality of 2-2-th connection lines 122b may be formed of the same material as the plurality of 1-2-th connection lines 121b.

The plurality of 2-3-th connection lines 122c may be disposed on the first insulating layer 115a. The plurality of 2-3-th connection lines 122c may be disposed in the second non-active area NA2. The 2-3-th connection line 122c may be electrically connected to the 2-2-th connection line 122b through a contact hole of the first insulating layer 115a. Accordingly, a signal from the flexible circuit board (or flexible film) 400 and the printed circuit board 500 may be transmitted to the 2-1-th connection line 122a through the 2-3-th connection line 122c and the 2-2-th connection line 122b. For example, the plurality of 2-3-th connection lines 122c may be disposed on the same layer as the plurality of 1-3-th connection lines 121c. For example, the plurality of 2-3-th connection lines 122c may be formed of the same material as the plurality of 1-3-th connection lines 121c.

The plurality of 2-4-th connection lines 122d may be disposed on the second insulating layer 115b. The plurality of 2-4-th connection lines 122d may be disposed in the second non-active area NA2. The 2-4-th connection line 122d may be electrically connected to the 2-3-th connection line 122c through a contact hole of the second insulating layer 115b. Accordingly, a signal from the flexible circuit board (or flexible film) 400 and the printed circuit board 500 may be transmitted to the 2-1-th connection line 122a through the 2-4-th connection line 122d, the 2-3-th connection line 122c, and the 2-2-th connection line 122b. For example, the plurality of 2-4-th connection lines 122d may be disposed on the same layer as the plurality of 1-4-th connection lines 121d. For example, the plurality of 2-4-th connection lines 122d may be formed of the same material as the plurality of 1-4-th connection lines 121d.

The plurality of first connection lines 121 and the plurality of second connection lines 122 may be formed of any one of a conductive material having excellent ductility or various conductive materials used for the active area AA. For example, the second connection line 122 which is partially disposed in the bending area BA may be configured by a conductive material having excellent ductility, such as gold (Au), silver (Ag), or aluminum (Al), but the example embodiments of the present disclosure are not limited thereto. As another example, the plurality of first connection lines 121 and the plurality of second connection lines 122 may be configured by molybdenum (Mo), chrome (Cr), titanium (Ti), nickel (Ni), neodymium (Nd), copper (Cu), and an alloy of silver (Ag) and magnesium (Mg) or an alloy thereof, but the example embodiments of the present disclosure are not limited thereto.

The third insulating layer 115c may be disposed on the plurality of first connection lines 121 and the plurality of second connection lines 122. The third insulating layer 115c may be entirely disposed in the active area AA and the non-active area NA, but the example embodiments of the present disclosure are not limited thereto. For example, the third insulating layer 115c may be disposed on the second insulating layer 115b in the active area AA and the second non-active area NA2 (or the pad area). The third insulating layer 115c may be configured by an organic insulating material, but the example embodiments of the present disclosure are not limited thereto. For example, the third insulating layer 115c may be configured by a photo resist, polyimide (PI), or photo acrylic-based material, but the example embodiments of the present disclosure are not limited thereto.

A plurality of banks BNK may be disposed on the third insulating layer 115c in the active area AA. The plurality of banks BNK may be disposed so as to overlap each of the plurality of sub pixels. One or more same type micro LEDs (ED) may be disposed above each of the plurality of banks BNK.

A plurality of signal lines TL may be disposed on the third insulating layer 115c in the active area AA. The plurality of signal lines TL may be disposed in an area between the plurality of banks BNK. For example, the plurality of signal lines TL may be disposed to be adjacent to any one of the plurality of banks BNK. The plurality of signal lines TL may be electrically connected to the plurality of 1-4-th connection lines 121d. For example, the plurality of signal lines TL may be electrically connected to the 1-4-th connection line 121d through a contact hole of the third insulating layer 115c.

A plurality of contact electrodes CCE may be disposed on the third insulating layer 115c in the active area AA. The plurality of contact electrodes CCE may supply a cathode voltage from the pixel driving circuit PD to the second electrode CE2.

The first electrode CE1 may be disposed on the bank BNK. For example, the first electrode CE1 may be disposed to extend toward the top of the bank BNK from the adjacent signal line TL. The first electrode CE1 may be disposed on the top surface of the bank BNK and the side surface of the bank BNK. For example, the first electrode CE1 may be disposed to extend from the signal line TL on the top surface of the third insulating layer 115c to the side surface of the bank BNK and the top surface of the bank BNK.

Referring to FIG. 9, the first electrode CE1 may be configured by a plurality of conductive layers. For example, the first electrode CE1 may include a first conductive layer CE1a, a second conductive layer CE1b, a third conductive layer CE1c, and a fourth conductive layer CE1d, but the example embodiments of the present disclosure are not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c. For example, the first conductive layer CE1a, the second conductive layer CE1b, the third conductive layer CE1c, and the fourth conductive layer CE1d may be configured by titanium (Ti), molybdenum (Mo), aluminum (Al), or titanium (Ti) and indium tin oxide (ITO), but the example embodiments of the present disclosure are not limited thereto.

According to one or more aspects of the present disclosure, some conductive layer having a good reflection efficiency, among a plurality of conductive layers which configures the first electrode CE1 may be configured as an alignment key for alignment of the micro LED ED and/or a reflective plate. For example, the second conductive layer CE1b, among the plurality of conductive layers of the first electrode CE1, may include a reflective material. For example, the second conductive layer CE1b may include aluminum (Al), but the example embodiments of the present disclosure are not limited thereto. Therefore, the second conductive layer CE1b may be configured as a reflective plate. Further, the second conductive layer CE1b has a high reflection efficiency to be easily identified during the manufacturing process so that a position of the micro LED ED or a transfer position may be aligned based on the second conductive layer CE1b.

For example, in order to configure the second conductive layer CE1b as a reflective plate, the third conductive layer CE1c and the fourth conductive layer CE1d which cover the second conductive layer CE1b may be partially removed or etched. For example, a part of the third conductive layer CE1c and the fourth conductive layer CE1d disposed on the bank BNK is removed or etched to expose a top surface of the second conductive layer CE1b. For example, a center portion and an edge portion (or a boundary portion) of the third conductive layer CE1c and the fourth conductive layer CE1d in which a solder pattern SDP is disposed may remain and the remaining portion excluding the portions may be removed. For example, an edge portion (or a boundary portion) of each of the third conductive layer CE1c formed of titanium (Ti) and the fourth conductive layer CE1d formed of indium tin oxide (ITO) may not be etched. Therefore, corrosion of another conductive layer of the first electrode CE1 caused by tetramethylammonium hydroxide (TMAH) solution which is used for the mask process of the first electrode CE1 may be suppressed.

According to one or more aspects of the present disclosure, the first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which is adhesive to the solder pattern SPD, and has anti-corrosion and acid resistance, but the example embodiments of the present disclosure are not limited thereto.

The first conductive layer CE1a, the second conductive layer CE1b, the third conductive layer CE1c, and the fourth conductive layer CE1d are sequentially deposited, and then are subject to a photolithographic process and an etching process to be patterned. However, but the example embodiments of the present disclosure are not limited thereto.

According to the present specification, the signal line TL, the contact electrode CCE, and the first pad electrode PE1 disposed on the same layer as the first electrode CE1 may be configured by multiple layers of conductive materials, but the example embodiments of the present disclosure are not limited thereto. For example, the signal line TL, the contact electrode CCE, and the first pad electrode PE1 may be formed of multiple layers of indium tin oxide (ITO)/titanium (Ti)/aluminum (Al)/titanium (Ti), but the example embodiments of the present disclosure are not limited thereto.

According to one or more aspects of the present disclosure, in each of the plurality of sub pixels, a solder pattern SDP may be disposed on the first electrode CE1. The solder pattern SDP may be disposed between the first electrode CE1 and the anode electrode 134 of the micro LED ED. The solder pattern SDP bonds the micro LED ED to the first electrode CE1 to electrically connect the first electrode CE1 and the micro LED ED. For example, the first electrode CE1 and the anode electrode 134 of the micro LED ED may be electrically connected through eutectic bonding using the solder pattern SDP, but the example embodiments of the present disclosure are not limited thereto. For example, when the solder pattern SDP is configured by indium (In) and the anode electrode 134 of the micro LED ED is configured by gold (Au), the solder pattern SDP and the anode electrode 134 are bonded by applying heat and a pressure during the transfer process of the micro LED ED. The micro LED ED may be bonded to the solder pattern SDP and the first electrode CE1 using the eutectic bonding without a separate adhesive material. For example, the solder pattern SDP may be configured by indium (Id), tin (Sn), or an alloy thereof, but the example embodiments of the present disclosure are not limited thereto. For example, the solder pattern SDP may be a bonding pad or an adhesive pad, but the example embodiments of the present disclosure are not limited thereto.

According to the present specification, the passivation layer 116 may be disposed on the plurality of signal lines TL, the plurality of first electrodes CE1, the plurality of contact electrodes CCE, and the third insulating layer 115c. For example, the passivation layer 116 may be disposed in the active area AA, the first non-active area NA1, and the second non-active area NA2. For example, the passivation layer may be disposed on the plurality of organic insulating layers in the non-active area NA. A part of the passivation layer 116 disposed in the bending area BA may be removed. In the second non-active area NA2, the passivation layer 116 may overlap at least some of the plurality of first pad electrodes PE1. For example, a part of the passivation layer 116 which covers the plurality of first pad electrodes PE1 may be removed. In the second non-active area NA2, at least a part of the passivation layer 116 may be disposed in an opening area (e.g. the hole H) of the third insulating layer 115c. For example, the passivation layer 116 may be disposed so as to overlap at least a part of the first pad electrode PE1 and the plurality of holes H. For example, in the second non-active area NA2, a part of the passivation layer 116 which is disposed in the hole H of the third insulating layer 115c may be removed. The passivation layer 116 is disposed so as to cover the remaining area excluding an area in which the bending area BA, the plurality of first pad electrodes PE1, and the solder pattern SDP are disposed to reduce permeation of moisture or impurity introduced to the micro LED ED. For example, the passivation layer 116 may be configured by a single layer or multiple layers of silicon oxide (SiOx) or silicon nitride (SiNx), but the example embodiments of the present disclosure are not limited thereto. For example, the passivation layer 116 may be a protection layer or an insulating layer, but the example embodiments of the present disclosure are not limited thereto. For example, the passivation layer 116 may include a hole through which the solder pattern SDP is exposed.

In each of the plurality of sub pixels, the micro LED ED may be disposed on the solder pattern SDP. A first micro LED 130 may be disposed in the first sub pixel SP1. A second micro LED 140 may be disposed in the second sub pixel SP2. A third micro LED 150 may be disposed in the third sub pixel SP3.

The micro LED ED may be formed on a silicon wafer using metal organic chemical vapor deposition (MOCVD), chemical vapor deposition (CVD), plasma-enhanced chemical vapor deposition (PECVD), molecular beam epitaxy (MBE), hydride vapor phase epitaxy (HVPE), or a sputtering method. However, the example embodiments of the present disclosure are not limited thereto.

Referring to FIG. 9, the first micro LED 130 may include an anode electrode 134, a first semiconductor layer 131 disposed on the anode electrode 134, an active layer 132 disposed on the first semiconductor layer 131, a second semiconductor layer 133 disposed on the active layer 132, a cathode electrode 135 disposed on the second semiconductor layer 133, and an encapsulation film 136, but the example embodiments of the present disclosure are not limited thereto. For example, the encapsulation film 136 may not be included in the first micro LED 130.

The first semiconductor layer 131 may be disposed on the solder pattern SDP. The second semiconductor layer 133 may be disposed on the first semiconductor layer 131.

For example, one of the first semiconductor layer 131 and the second semiconductor layer 133 may be implemented by a compound semiconductor, such as a III-V group or a II-VI group and may be doped with an impurity (or dopant). For example, one of the first semiconductor layer 131 and the second semiconductor layer 133 may be an n-type impurity doped semiconductor layer and the other one may be a p-type impurity doped semiconductor layer, but the example embodiments of the present disclosure are not limited thereto. For example, one or more of the first semiconductor layer 131 and the second semiconductor layer 133 may be a layer in which n-type or p-type impurity is doped on a material, such as gallium nitride (GaN), gallium phosphide (GaP), gallium arsenide phosphide (GaAsP), aluminum gallium indium phosphide (AlGaInP), indium aluminum phosphide (InAlP), aluminum gallium nitride (AlGaN), aluminum indium nitride (AlInN), aluminum indium gallium nitride (AlInGaN), aluminum gallium arsenide (AlGaAs), or gallium arsenide (GaAs). However, the example embodiments of the present disclosure are not limited thereto. For example, the n-type impurity may be silicon (Si), germanium (Ge), selenium (Se), carbon (C), tellurium (Te), or tin (Sn), but the example embodiments of the present disclosure are not limited thereto. For example, the p-type impurity may be magnesium (Mg), zinc (Zn), calcium (Ca), strontium (Sr), barium (Ba), or beryllium (Be), but the example embodiments of the present disclosure are not limited thereto.

For example, each the first semiconductor layer 131 and the second semiconductor layer 133 may be a nitride semiconductor including an n-type impurity or a nitride semiconductor including a p-type impurity, but the example embodiments of the present disclosure are not limited thereto. For example, the first semiconductor layer 131 may be a nitride semiconductor including a p-type impurity and the second semiconductor layer 133 may be a nitride semiconductor including an n-type impurity, but the example embodiments of the present disclosure are not limited thereto.

The active layer 132 may be disposed between the first semiconductor layer 131 and the second semiconductor layer 133. The active layer 132 is supplied with holes and electrons from the first semiconductor layer 131 and the second semiconductor layer 133 to emit light. For example, the active layer 132 may be configured by one of a single well structure, a multi-well structure, a signal quantum well structure, a multi-quantum well (MQW) structure, a quantum dot structure, and a quantum line structure, but the example embodiments of the present disclosure are not limited thereto. For example, the active layer 132 may be configured by indium gallium nitride (InGaN) or gallium nitride (GaN), but the example embodiments of the present disclosure are not limited thereto.

As another example, the active layer 132 may have a multi quantum well (MQW) structure having a well layer and a barrier layer with a band gap higher than the well layer. For example, in the active layer 132, InGaN may be configured as a well layer and an AlGaN layer may be configured as a barrier layer, but the example embodiments of the present disclosure are not limited thereto.

The anode electrode 134 may be disposed between the first semiconductor layer 131 and the solder pattern SDP. For example, the anode electrode 134 may electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be configured by a conductive material which may form eutectic bonding with the solder pattern SDP, but the example embodiments of the present disclosure are not limited thereto. For example, the anode electrode 134 may be configured by gold (Au), tin (Sn), tungsten (W), silicon (Si), silver (Ag), titanium (Ti), iridium (Ir), chromium (Cr), indium (In), zinc (Zn), lead (Pb), nickel (Ni), platinum (Pt), and copper (Cu), or an alloy thereof, but the example embodiments of the present disclosure are not limited thereto.

The cathode electrode 135 may be disposed on the second semiconductor layer 133. For example, the cathode electrode 135 may electrically connect the second semiconductor layer 133 and the second electrode CE2. A cathode voltage output from the pixel driving circuit PD may be applied to the second semiconductor layer 133 through the contact electrode CCE, the second electrode CE2, and the cathode electrode 135. The cathode electrode 135 may be configured by a transparent conductive material to allow light emitted from the micro LED ED to be directed to the top of the micro LED ED, but the example embodiments of the present disclosure are not limited thereto. For example, the cathode electrode 135 is configured by a material, such as indium tin oxide (ITO), indium zinc oxide (IZO), or indium gallium zinc oxide (IGZO), but the example embodiments of the present disclosure are not limited thereto.

The encapsulation film 136 may be disposed in at least a part of the first semiconductor layer 131, the active layer 132, the second semiconductor layer 133, the anode electrode 134, and the cathode electrode 135. For example, the encapsulation film 136 may enclose at least a part of the first semiconductor layer 131, the active layer 132, the second semiconductor layer 133, the anode electrode 134, and the cathode electrode 135.

For example, the encapsulation film 136 may protect the first semiconductor layer 131, the active layer 132, and the second semiconductor layer 133. For example, the encapsulation film 136 may be disposed on a side surface of the first semiconductor layer 131, a side surface of the active layer 132, and a side surface of the second semiconductor layer 133.

For example, the encapsulation film 136 may be disposed on at least a part of the anode electrode 134 and the cathode electrode 135, for example, on an edge portion (or a boundary portion or one side) of the anode electrode 134 and an edge portion (or a boundary portion or one side) of the cathode electrode 135. At least a part of the anode electrode 134 may be exposed from the encapsulation film 136 so that the anode electrode 134 and the solder pattern SDP may be connected. For example, at least a part of the cathode electrode 135 may be exposed from the encapsulation film 136 so that the cathode electrode 135 and the second electrode CE2 may be connected. For example, the encapsulation film 136 may be formed of an insulating material, such as silicon nitride (SiNx) or silicon oxide (SiOx), but the example embodiments of the present disclosure are not limited thereto.

As another example, the encapsulation film 136 may have a structure in which a reflective material is dispersed in a resin layer, but the example embodiments of the present disclosure are not limited thereto. For example, the encapsulation film 136 may be manufactured with reflectors with various structures, but the example embodiments of the present disclosure are not limited thereto. Light emitted from the active layer 132 may be upwardly reflected by the encapsulation film 136 so that light extraction efficiency may be improved. For example, the encapsulation film 136 may be a reflective layer, but the example embodiments of the present disclosure are not limited thereto.

According to the present specification, the micro LED ED may have a vertical structure, but the example embodiments of the present disclosure are not limited thereto. For example, the micro LED ED may also have a lateral structure or a flip-chip structure.

The first micro LED 130 has been described with reference to FIG. 9 and the second micro LED 140 and the third micro LED 150 may have the substantially same structure as the first micro LED 130. For example, the second micro LED 140 and the third micro LED 150 may be substantially the same as the first semiconductor layer 131, the active layer 132, the second semiconductor layer 133, the anode electrode 134, the cathode electrode 135, and the encapsulation film 136 of the first micro LED 130.

According to the present specification, in the active area AA, a first optical layer 117a which encloses the plurality of micro LEDs (ED) may be disposed. For example, the first optical layer 117a may be disposed so as to cover the plurality of micro LEDs (ED) and the bank BNK in the area of the plurality of sub pixels. For example, the first optical layer 117a may cover the bank BNK, a part of the passivation layer 116 and between the plurality of micro LEDs (ED). The first optical layer 117a may be disposed or cover between the plurality of micro LEDs (ED) and between the plurality of banks BNK included in one pixel PX. Referring to FIG. 5 together, for example, the first optical layers 117a extend in the first direction X and are spaced apart from each other in the second direction Y. For example, the first optical layer 117a may be disposed so as to enclose side portions of the micro LED ED and the bank BNK between the passivation layer 116 and the second electrode CE2, but the example embodiments of the present disclosure are not limited thereto. For example, the first optical layer 117a may be a diffusion layer or a side wall diffusion layer, but the example embodiments of the present disclosure are not limited thereto.

The first optical layer 117a may include an organic insulating material in which micro particles are dispersed, but the example embodiments of the present disclosure are not limited thereto. For example, the first optical layer 117a may be configured by siloxane in which micro metal particles, such as titanium dioxide (TiO₂) particles, are dispersed, but the example embodiments of the present disclosure are not limited thereto. Light from the plurality of micro LEDs (ED) is scattered by micro particles dispersed in the first optical layer 117a to be emitted to the outside of the display device 1000. Accordingly, the first optical layer 117a may improve extraction efficiency of light emitted from the plurality of micro LEDs (ED).

For example, the first optical layer 117a may be disposed in each of the plurality of pixels PX or disposed in some pixel PX disposed in the same row together, but the example embodiments of the present disclosure are not limited thereto. For example, the first optical layer 117a is disposed in each of the plurality of pixels PX or the plurality of pixels PX may share one first optical layer 117a. As another example, each of the plurality of sub pixels separately includes the first optical layer 117a, but the example embodiments of the present disclosure are not limited thereto.

According to one or more aspects of the present disclosure, in the active area AA, a second optical layer 117b may be disposed on the passivation layer 116. For example, the second optical layer 117b may be disposed so as to enclose the first optical layer 117a. For example, the second optical layer 117b may be in contact with a side surface of the first optical layer 117a. For example, the second optical layer 117b may be disposed in an area between the plurality of pixels PX. However, the example embodiments of the present disclosure are not limited thereto. For example, the second optical layer 117b may be a diffusion layer, a diffusion layer window, or a window diffusion layer, but the example embodiments of the present disclosure are not limited thereto.

The second optical layer 117b may be configured by an organic insulating material, but the example embodiments of the present disclosure are not limited thereto. The second optical layer 117b may be configured by the same material as the first optical layer 117a, but the example embodiments of the present disclosure are not limited thereto. For example, the first optical layer 117a may include micro particles, but the second optical layer 117b may not include micro particles. For example, the second optical layer 117b may be configured by siloxane, but the example embodiments of the present disclosure are not limited thereto.

For example, a thickness of the first optical layer 117a may be smaller than a thickness of the second optical layer 117b, but the example embodiments of the present disclosure are not limited thereto. Accordingly, in the plan view, an area in which the first optical layer 117a is disposed may include a concave portion which is inwardly dented from an upper surface of the second optical layer 117b.

According to one or more aspects of the present disclosure, the second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 may be disposed on the plurality of micro LEDs (ED). For example, the second electrode CE2 may include a transparent conductive oxide, such as indium tin oxide (ITO) or indium zinc oxide (IZO), but the example embodiments of the present disclosure are not limited thereto. For example, the second electrode CE2 may be disposed to be in contact with the cathode electrode 135. For example, the second electrode CE2 may overlap the first optical layer 117a. For example, the second electrode CE2 may cover a plane surface at the outside of the first optical layer 117a.

Referring to FIG. 7, for example, the second electrode CE2 may continuously extend to the first direction X of the substrate 110. Accordingly, the second electrode may be commonly connected to the plurality of pixels PX disposed in the first direction X of the substrate 110. For example, the second electrode CE2 may be commonly connected to the plurality of pixels PX.

According to the present specification, the second electrode CE2 may continuously extend on the first optical layer 117a, the second optical layer 117b, and the micro LED ED. The area in which the first optical layer 117a is disposed may include a concave portion which is inwardly dented from an upper surface of the second optical layer 117b. Accordingly, the first part of the second electrode CE2 disposed on the first optical layer 117a is disposed along the concave portion so that the first part may be disposed to be lower than the second part of the second electrode CE2 disposed on the second optical layer 117b.

The third optical layer 117c may be disposed on the second electrode CE2. The third optical layer 117c may be disposed so as to overlap the plurality of micro LEDs (ED) and the first optical layer 117a. The third optical layer 117c is disposed above the second electrode CE2 and the plurality of micro LEDs (ED) so that mura which may be generated in a part of the plurality of micro LEDs (ED) may be reduced. For example, when the plurality of micro LEDs (ED) is transferred onto the substrate 110 of the display device 1000, an area in which the interval between the plurality of micro LEDs (ED) is not uniform may be caused due to a process deviation. When the interval between the plurality of micro LEDs (ED) is not uniform, an emission area of each of the plurality of micro LEDs (ED) is not uniformly disposed so that the mura may be visible to a user. Accordingly, the third optical layer 117c which is configured to uniformly diffuse light is configured above the plurality of micro LEDs (ED) so that light emitted from some micro LED ED which is visible as mura may be reduced. Accordingly, light emitted from the plurality of micro LEDs (ED) is uniformly diffused by the third optical layer 117c to be extracted to the outside of the display device 1000 so that the luminance uniformity of the display device 1000 may be improved.

The third optical layer 117c may be configured by an organic insulating material in which micro particles are dispersed, but the example embodiments of the present disclosure are not limited thereto. For example, the third optical layer 117c may be configured by siloxane in which micro metal particles, such as titanium dioxide (TiO₂) particles, are dispersed, but the example embodiments of the present disclosure are not limited thereto. For example, the third optical layer 117c is configured by the same material as the first optical layer 117a, but the example embodiments of the present disclosure are not limited thereto. For example, the third optical layer 117c may be a diffusion layer or an upward diffusion layer, but the example embodiments of the present disclosure are not limited thereto.

According to the present specification, light from the plurality of micro LEDs (ED) is scattered by micro particles dispersed in the third optical layer 117c to be emitted to the outside of the display device 1000. The third optical layer 117c uniformly mixes light emitted from the plurality of micro LEDs (ED) to further improve the luminance uniformity of the display device 1000. The light extraction efficiency of the display device 1000 may be improved by light scattered from the plurality of micro particles so that the display device 1000 may be driven at a low power.

In the active area AA, a black matrix BM may be disposed on the second electrode CE2, the first optical layer 117a, the second optical layer 117b, and the third optical layer 117c. For example, the contact hole of the second optical layer 117b may be filled with the black matrix BM. The black matrix BM is configured to cover the active area AA to reduce color mixture and external light reflection of light of the plurality of sub pixels. For example, the black matrix BM is disposed in the contact hole through which the second electrode CE2 and the contact electrode CCE are connected so that light leakage between the plurality of adjacent sub pixels is suppressed.

For example, the black matrix BM may be configured by an opaque material, but the example embodiments of the present disclosure are not limited thereto. For example, the black matrix BM may be configured by an organic insulating material to which black pigment or black dye is added, but the example embodiments of the present disclosure are not limited thereto.

In the active area AA, a cover layer 118 may be disposed on the black matrix BM. The cover layer 118 may protect configurations below the cover layer 118. For example, the cover layer 118 may be configured by an organic insulating material, but the example embodiments of the present disclosure are not limited thereto. For example, the cover layer 118 may be configured by a photo resist, polyimide (PI), or photo acrylic-based material, but the example embodiments of the present disclosure are not limited thereto. For example, the cover layer 118 may be an over coating layer or an insulating layer, but the example embodiments of the present disclosure are not limited thereto.

A polarization layer 293 may be disposed on the cover layer 118 by means of the first adhesive layer 291. A cover member 200 may be disposed on the polarization layer 293 by means of the second adhesive layer 295. For example, the first adhesive layer 291 and the second adhesive layer 295 may include an optically clear adhesive (OCA), an optically clear resin (OCR), or a pressure sensitive adhesive (PSA), but the example embodiments of the present disclosure are not limited thereto.

According to the present specification, the plurality of first pad electrodes PE1 may be disposed on the third insulating layer 115c in the second non-active area NA2. For example, at least some of the plurality of first pad electrodes PE1 may be exposed from the passivation layer 116. For example, the plurality of first pad electrodes PE1 may be electrically connected to the 2-4-th connection line 122d through a contact hole of the third insulating layer 115c. Referring to FIG. 3 together, for example, the plurality of first pad electrodes PE1 extends in the second direction Y toward the active area AA and is spaced apart from each other in the first direction X which is perpendicular to the second direction Y.

In the second non-active area NA2, a total thickness of the plurality of organic insulating layers below the first pad electrode PE1 varies in each area. In the second non-active area NA2, a total thickness of the plurality of organic insulating layers in an area overlapping the first pad electrode PE1 is larger than a total thickness of the plurality of organic insulating layers in an area between the plurality of first pad electrodes PE1 which is spaced apart from each other in the first direction X.

For example, the first insulating layer 115a, the second insulating layer 115b, and the third insulating layer 115c may be sequentially disposed below the plurality of first pad electrodes PE1. At this time, in an area between the plurality of first pad electrodes PE1 which does not overlap the plurality of first pad electrodes PE1, the third insulating layer 115c may include a plurality of insulating patterns which is formed by etching at least a part of the top surface. A plurality of opening areas, such as a plurality of grooves or the plurality of holes H, may be formed by the plurality of insulating patterns between the plurality of first pad electrodes PE1. As described above, the plurality of opening areas is formed in a partial area of the third insulating layer 115c so that a total thickness of the plurality of organic insulating layers in the area where the plurality of opening areas is formed may be reduced.

As another example, the third insulating layer 115c may include a plurality of opening areas (e.g., holes H) formed between the plurality of first pad electrodes PE1. In the area which overlaps the plurality of first pad electrodes PE1, the first insulating layer 115a, the second insulating layer 115b, and the third insulating layer 115c may be disposed. In contrast, in an area which does not overlap plurality of first pad electrodes PE1, the first insulating layer 115a and the second insulating layer 115b may be disposed. As described above, in at least a part of the area which does not overlap the plurality of first pad electrodes PE1, the third insulating layer 115c may not be disposed. In the non-active area AA, at least a part of the top surface of the second insulating layer 115b (i.e., a layer disposed below the top layer of the plurality of organic insulating layers) may be exposed by the plurality of opening areas. As described above, the number of the plurality of organic insulating layers disposed in an area which overlaps the plurality of first pad electrodes PE1 may be different from the number of the plurality of organic insulating layers disposed in an area which does not overlap the plurality of first pad electrodes PE1.

The plurality of holes H (referring to claim 10) may be disposed between the plurality of first pad electrodes PE1. Referring to FIG. 3 together, for example, the plurality of holes H are disposed between the plurality of the pad electrode (PE). The plurality of holes H may extend toward the active area AA in the second direction Y. As another example, one end portion of the plurality of holes H may be adjacent to the active area more than one end portion of the second pad electrode PE2 which is included in the flexible circuit board, but the example embodiments of the present disclosure are not limited thereto.

The passivation layer 116 may be disposed in a partial area in the plurality of holes H. For example, the passivation layer 116 may be removed from a partial area in the plurality of holes H, but the example embodiments of the present disclosure are not limited thereto. A width of the plurality of holes H may be reduced toward the lower substrate 110, but the example embodiments of the present disclosure are not limited thereto.

The adhesive layer ACF may be disposed on the plurality of first pad electrodes PE1. The adhesive layer ACF may be an adhesive layer in which a conductive adhesive member is dispersed into an insulating material and for example, may be an anisotropic conductive film, but the example embodiments of the present disclosure are not limited thereto. The conductive adhesive member may include a plurality of conductive balls CB. Therefore, when heat or a pressure is applied to the adhesive layer ACF, the plurality of conductive balls CB is electrically connected in a portion applied with the heat or pressure to have a conductive property.

The adhesive layer ACF is disposed between the plurality of first pad electrodes PE1 and the flexible circuit board (or flexible film) 400 so that the plurality of second pad electrodes PE2 of the flexible circuit board (or flexible film) 400 may be attached or bonded to the plurality of first pad electrodes PE1. Therefore, the plurality of first pad electrodes PE1 and the plurality of second pad electrodes PE2 of the flexible circuit board (or flexible film) 400 may be electrically connected to each other. For example, at least one conductive ball CB may be in contact with the plurality of first pad electrodes PE1 and the plurality of second pad electrodes PE2, but the example embodiments of the present disclosure are not limited thereto. As shown in FIG. 8, in the non-active area NA, the flexible circuit board (or flexible film) 400 may be disposed on the plurality of first pad electrodes PE1. The conductive adhesive member may be disposed between the plurality of first pad electrodes PE1 and the flexible circuit board (or flexible film) 400. The conductive adhesive member may be disposed to be filled in the plurality of opening areas (e.g., the holes H). Some of the plurality of conductive balls CB may be disposed in the plurality of holes H.

The adhesive layer ACF may be disposed to be filled in the plurality of holes H disposed between the plurality of first pad electrodes PE1. Therefore, some of the plurality of conductive balls CB may be dispersed in the plurality of holes H. For example, some of the plurality of conductive balls CB may be disposed in a space formed connected between the plurality of holes H and the plurality of first pad electrodes PE1 and the plurality of second pad electrodes PE2, but the example embodiments of the present disclosure are not limited thereto.

The flexible circuit board (or flexible film) 400 including a second pad electrode PE2 may be disposed on the adhesive layer ACF. The flexible circuit board (or flexible film) 400 may be electrically connected to the plurality of first pad electrodes PE1 through the adhesive layer ACF and the second pad electrodes PE2 connected thereto. Accordingly, a signal output from the flexible circuit board (or flexible film) 400 and the printed circuit board 500 may be transmitted to the pixel driving circuit PD of the active area AA through the plurality of first pad electrodes PE1, the 2-4-th connection line 122d, the 2-3-th connection line 122c, the 2-2-th connection line 122b, and the 2-1-th connection line 122a.

As described above, when a pad unit including the flexible circuit board is bonded to the display panel, an adhesive member including a plurality of conductive balls may be used. However, the plurality of conductive balls is irregularly dispersed in the adhesive member so that it is difficult to control an interval between the plurality of conductive balls. Therefore, the plurality of conductive balls clumps in a small space formed between the plurality of pad electrodes. Further, even though the plurality of conductive balls is dispersed to be aligned in one line in the adhesive member, the conductive balls aligned in one line is concentrated in the small space formed between the plurality of pad electrodes. Therefore, an aligned angular gradient is increased by the interference by the plurality of pad electrodes, which results in the clumping of the plurality of conductive balls. As described above, when the plurality of conductive balls clumps between the plurality of pad electrodes, a problem in that the adjacent pad electrodes are electrically shorted occurs. If the adjacent pad electrodes are electrically connected by the short-circuit, as compared with the normal pixel, a luminance is not uniform and an unnecessary signal is applied to allow a pixel which should not emit light to emit light, which results in poor display quality of the display device. Further, when the plurality of conductive balls clumps between the plurality of pad electrodes, the area in which the plurality of conductive balls clumps is vulnerable to burnt-out caused by external factors. Therefore, there is a problem in that in the area in which the plurality of conductive balls clumps, the burnt-out due to the external factors may be concentrated more than in a normal area in which the conductive balls do not clump.

In the display device 1000 according to the example embodiment of the present disclosure, the total thickness of the plurality of organic insulating layers in an area which overlaps the plurality of first pad electrodes PE1 is larger than the total thickness of the plurality of organic insulating layers in an area which does not overlap the plurality of first pad electrodes PE1. For example, a top layer (e.g., the third insulating layer 115c) of the plurality of organic insulating layers between the plurality of first pad electrodes PE1 may include a plurality of holes H disposed between the plurality of first pad electrodes PE1. Therefore, in the display device 1000 according to the example embodiment of the present disclosure, a space between the plurality of first pad electrodes PE1 may expand by the plurality of holes H so that an area between the plurality of first pad electrodes PE1 and the plurality of second pad electrodes PE2 in which the plurality of conductive balls CB is dispersed also expands. Therefore, a sufficient space may be provided between the plurality of first pad electrodes PE1 and the plurality of second pad electrodes PE2 so as not to allow the plurality of conductive balls CB to clump each other. That is, the clumping of the plurality of conductive balls CB between the plurality of first pad electrodes PE1 and the plurality of second pad electrodes PE2 may be suppressed. By doing this, the short-circuit between the plurality of first pad electrodes PE1 or the plurality of second pad electrodes PE2 caused by the clumping of the plurality of conductive balls CB may be suppressed.

Further, a burnt defect which may be caused by the clumping of the plurality of conductive balls CB between the plurality of first pad electrodes PE1 and the plurality of second pad electrodes PE2 may be minimized.

Further, the display device 1000 according to the example embodiment of the present disclosure suppresses the defect generated in the pad unit PAD in which the plurality of first pad electrodes PE1 is disposed to improve the lifespan of the display device 1000. Accordingly, the display device 1000 according to the example embodiment of the present disclosure may be highly efficiently driven at a low power.

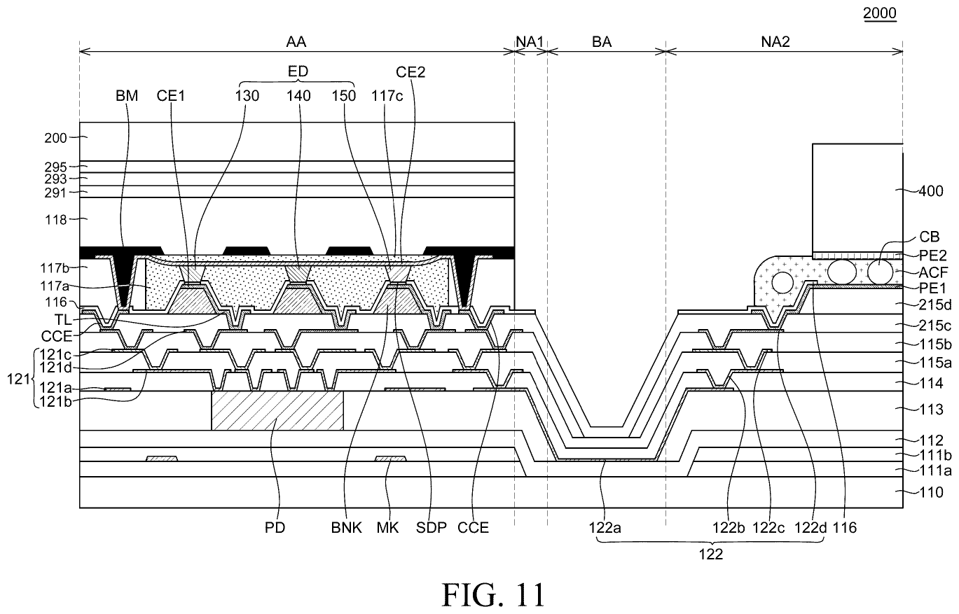

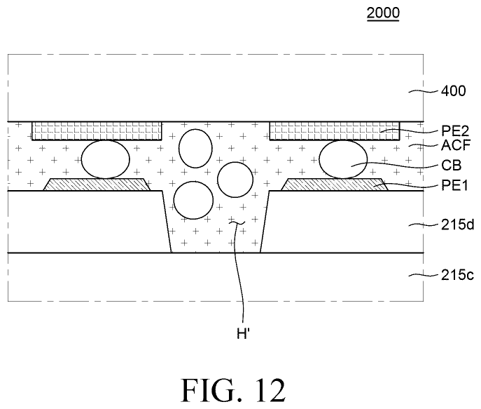

FIG. 11 is a cross-sectional view of a display device 2000 according to another example embodiment of the present disclosure. FIG. 11 is a cross-sectional view of the same area as in FIG. 8. FIG. 12 is an enlarged cross-sectional view of a display device 2000 according to another example embodiment of the present disclosure. For example, FIG. 11 is a cross-sectional view of an active area AA, a first non-active area NA1, a bending area BA, and a second non-active area NA2. For example, FIG. 12 is an enlarged cross-sectional view of a partial area of the second non-active area NA2. Configurations of a display device 2000 according to another example embodiment of the present disclosure other than a third insulating layer 215c and a fourth insulating layer 215d of the second non-active area NA2 are substantially the same as the display device 1000 of FIG. 8. Therefore, a redundant description will be omitted.

In a second non-active area NA2 of a display device 2000 according to another example embodiment of the present disclosure, a plurality of organic insulating layers including a first insulating layer 115a, a second insulating layer 115b, a third insulating layer 215c, and a fourth insulating layer 215d may be disposed.

The third insulating layer 215c may be disposed on the plurality of first connection lines 121 and the plurality of second connection lines 122. The third insulating layer 215c may be entirely disposed in the active area AA and the non-active area NA, but the example embodiments of the present disclosure are not limited thereto. The third insulating layer 215c may be configured by an organic insulating material, but the example embodiments of the present disclosure are not limited thereto. For example, the third insulating layer 215c may be configured by a photo resist, polyimide (PI), or photo acrylic-based material, but the example embodiments of the present disclosure are not limited thereto.

The third insulating layer 215c may be disposed in an area which overlaps the plurality of first pad electrodes PE1. Further, the third insulating layer 215c may be disposed between the plurality of first pad electrodes PE1 which is an area which does not overlap the plurality of first pad electrodes PE1. For example, in an area which overlaps the plurality of first pad electrodes PE1, the plurality of organic insulating layers including the first insulating layer 115a, the second insulating layer 115b, and the third insulating layer 215c may be disposed below the plurality of first pad electrodes PE1. Further, also in the area which does not overlap the plurality of first pad electrodes PE1 between the plurality of first pad electrodes PE1, the first insulating layer 115a, the second insulating layer 115b, and the third insulating layer 215c may be disposed.

A top surface of the third insulating layer 215c disposed in an area which overlaps the plurality of first pad electrodes PE1 may be disposed on the same plane as a top surface of the third insulating layer 215c disposed between the plurality of first pad electrodes PE1.

The fourth insulating layer 215d may be disposed on the third insulating layer 215c. Referring to FIG. 3 together, for example, a plurality of fourth insulating layers 215d may be spaced apart from each other in the first direction X. Therefore, in at least a part of the area which does not overlap the plurality of first pad electrodes PE1 between the plurality of first pad electrodes PE1, the fourth insulating layer 215d may not be disposed. For example, in the area which overlaps plurality of first pad electrodes PE1, the first insulating layer 115a, the second insulating layer 115b, the third insulating layer 215c, and the fourth insulating layer 215d may be disposed. In the area between the plurality of first pad electrodes PE1, the first insulating layer 115a, the second insulating layer 115b, and the third insulating layer 215c may be disposed.

The plurality of fourth insulating layers 215d is spaced apart from each other in an area between the plurality of first pad electrodes PE1 to form a plurality of holes H′. Therefore, at least a part of the top surface of the third insulating layer 215c may be exposed through the plurality of holes H′.

Referring to FIG. 3 together, for example, the plurality of fourth insulating layers 215d may extend in the second direction Y, respectively. As another example, one ends of the plurality of fourth insulating layers 215d may protrude to the second direction Y from one ends of the plurality of first pad electrodes PE1. Therefore, one ends of the plurality of fourth insulating layers 215d may be adjacent to the active area AA more than one ends of the plurality of first pad electrodes PE1.

The plurality of fourth insulating layers 215d may be disposed on the same layer as the plurality of banks BNK of the active area AA.

The plurality of fourth insulating layers 215d may be formed of the same material as the plurality of banks BNK. For example, the fourth insulating layer 215d may be formed of an organic insulating material. For example, the fourth insulating layer 215d may be configured by a photo resist, polyimide (PI), or acrylic-based material, but the example embodiments of the present disclosure are not limited thereto.

A total thickness of the plurality of fourth insulating layers 215d may be the same as that of the plurality of banks BNK, but the example embodiments of the present disclosure are not limited thereto.

The display device 2000 according to another example embodiment of the present disclosure includes fourth insulating layers 215d which are respectively disposed in areas overlapping the plurality of first pad electrodes PE1. As described above, the fourth insulating layer 215d is not disposed so that a plurality of holes H′ is disposed between the plurality of first pad electrodes PE1. A space between the plurality of first pad electrodes PE1 expands by the plurality of holes H′ as described above, so that an area between the plurality of first pad electrodes PE1 and the plurality of second pad electrodes PE2 in which the plurality of conductive balls CB is dispersed also expands. Therefore, the clumping of the plurality of conductive balls CB between the plurality of first pad electrodes PE1 and the plurality of second pad electrodes PE2 may be suppressed. Further, the short-circuit between the plurality of first pad electrodes PE1 or the plurality of second pad electrodes PE2 may be suppressed.

Further, a burnt defect which may be caused by the clumping of the plurality of conductive balls CB between the plurality of first pad electrodes PE1 and between the plurality of second pad electrodes PE2 may be minimized.

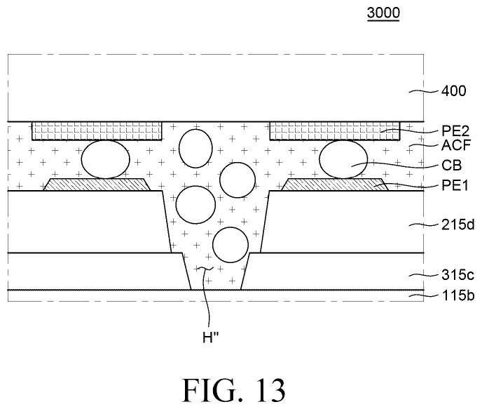

FIG. 13 is an enlarged cross-sectional view of a display device according to still another example embodiment of the present disclosure. For example, FIG. 13 is an enlarged cross-sectional view of a partial area of a second non-active area NA2 of a display device 3000 according to still another example embodiment of the present disclosure.

All configurations of a display device 3000 of FIG. 13 other than a third insulating layer 315c are substantially the same as the display device 2000 of FIG. 11, so that a redundant description will be omitted.

The third insulating layer 315c may be disposed on the plurality of first connection lines 121 and the plurality of second connection lines 122. The third insulating layer 315c may be entirely disposed in the active area AA and the non-active area NA, but the example embodiments of the present disclosure are not limited thereto. The third insulating layer 315c may be configured by an organic insulating material, but the example embodiments of the present disclosure are not limited thereto. For example, the third insulating layer 315c may be configured by a photo resist, polyimide (PI), or photo acrylic-based material, but the example embodiments of the present disclosure are not limited thereto.

The third insulating layer 315c may include a plurality of additional holes H″ formed in an area between the plurality of first pad electrodes PE1 in the second non-active area NA2. The plurality of additional holes H″ may be connected to the plurality of holes H′ formed by the plurality of fourth insulating layers 215d. For example, in the display device 3000 according to still another example embodiment of the present disclosure, the plurality of holes H′ of the display device 2000 of FIG. 11 may extend to the third insulating layer 315c.

The third insulating layer 315c may be disposed in an area which overlaps the plurality of first pad electrodes PE1. The third insulating layer 315c may not be disposed in an area between the plurality of first pad electrodes PE1. For example, in the area which overlaps plurality of first pad electrodes PE1, the first insulating layer 115a, the second insulating layer 115b, the third insulating layer 315c, and the fourth insulating layer 215d may be disposed. In the area which does not overlap the plurality of first pad electrodes PE1 between the plurality of first pad electrodes PE1, the first insulating layer 115a and the second insulating layer 115b may be disposed.

At least a part of the top surface of the second insulating layer 115b may be exposed by the plurality of holes H′ and the plurality of additional holes H″ in an area between the plurality of first pad electrodes PE1.

Referring to FIG. 3 together, for example, the plurality of additional holes H″ may extend in the second direction Y and may be spaced apart from each other in the first direction X. One ends of the plurality of additional holes H″ may be adjacent to the active area AA more than one ends of the plurality of first pad electrodes PE1.

The display device 3000 according to still another example embodiment of the present disclosure may further include a plurality of additional holes H″ connected from the plurality of holes H′. Therefore, a space in which the plurality of conductive balls CB is dispersed may expand more in an area between the plurality of first pad electrodes PE1. Further, the clumping of the plurality of conductive balls CB between the plurality of first pad electrodes PE1 and the plurality of second pad electrodes PE2 may be suppressed. Further, the short-circuit between the plurality of first pad electrodes PE1 or the plurality of second pad electrodes PE2 may be suppressed.

Further, a burnt defect which may be caused by the clumping of the plurality of conductive balls CB between the plurality of first pad electrodes PE1 and between the plurality of second pad electrodes PE2 may be minimized.

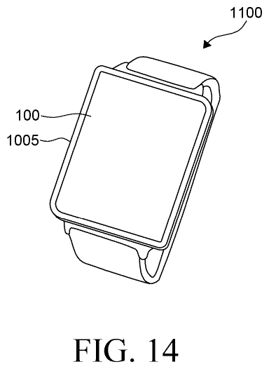

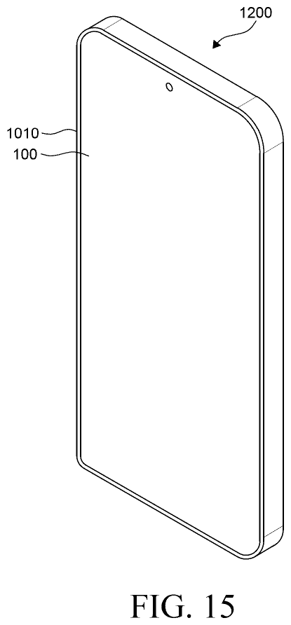

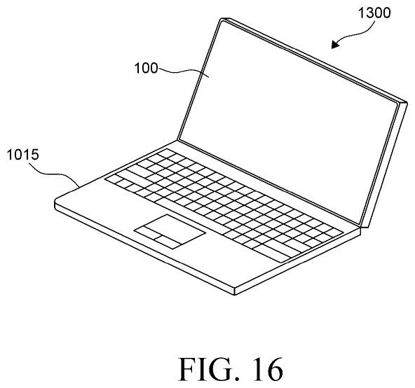

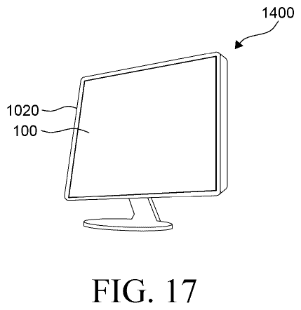

FIGS. 14 to 17 are views illustrating devices to which a display device according to example embodiments of the present disclosure is applied.

Referring to FIGS. 14 to 17, the display devices 1000, 2000, and 3000 according to the example embodiments of the present disclosure may be included in various devices or electronic devices. For example, referring to FIGS. 14 to 17, various electronic devices may include a wearable device 1100, a mobile device 1200, a notebook 1300, and a monitor or TV 1400, but the example embodiments of the present disclosure are not limited thereto.

Each of the wearable device 1100, the mobile device 1200, the notebook 1300, and a monitor or TV 1400 may include case units 1005, 1010, 1015, and 1020 and display panel 100 and the display devices 1000, 2000, and 3000 according to the example embodiments of the present disclosure which have been described in FIGS. 1 to 13, respectively.

For example, the display devices 1000, 2000, and 3000 according to the example embodiments of the present disclosure may be applicable to a mobile device, a video phone, a smart watch, a watch phone, a wearable device, a foldable device, a rollable device, a bendable device, a flexible device, a curved device, a sliding device, a variable device, an electronic note, an electronic book, a portable multimedia player (PMP), a personal digital assistant (PDA), an MP3 player, a mobile medical device, a desktop PC, a laptop PC, a netbook computer, a workstation, a navigation, a display device for a vehicle, a display device for a theater, a television, a wallpaper device, a signage device, a game device, a notebook, a monitor, a camera, a camcorder, and a consumer electronics device.

The example embodiments of the present disclosure can also be described as follows:

A display device according to an aspect of the present disclosure comprises a substrate including an active area and a non-active area, a pixel driving circuit disposed on the substrate in the active area, a plurality of micro LEDs which is disposed on the pixel driving circuit in the active area and is electrically connected to the pixel driving circuit, a plurality of organic insulating layers disposed on the substrate in each of the active area and the non-active area, and a plurality of first pad electrodes disposed on the plurality of organic insulating layers in the non-active area, wherein a total thickness of the plurality of organic insulating layers in an area overlapping the plurality of first pad electrodes is larger than a total thickness of the plurality of organic insulating layers in an area between the plurality of first pad electrodes.

In the non-active area, a top layer, among the plurality of organic insulating layers, may include a plurality of holes disposed between the plurality of first pad electrodes.

The plurality of holes may expose at least a part of a top surface of a layer disposed below the top layer of the plurality of organic insulating layers.

At least one of the plurality of organic insulating layers may extend between the pixel driving circuit and the plurality of micro LEDs in the active area.

A top layer of the plurality of organic insulating layers in the active area and a top layer of the plurality of organic insulating layers in the non-active area may be disposed on a same layer and, in the non-active area, the first pad electrode is in contact with the top layer of the plurality of organic insulating layers.

The top layer of the plurality of organic insulating layers in the non-active area and the top layer of the plurality of organic insulating layers in the active area may be connected to each other and are formed of a same material.

The display device may further comprise a plurality of banks disposed between the plurality of organic insulating layers and the plurality of micro LEDs in the active area, wherein the top layer of the plurality of organic insulating layers may be disposed on a same layer as the plurality of banks in the non-active area and the plurality of pad electrodes may be in contact with the top layer of the plurality of organic insulating layers.

The top layer of the plurality of organic insulating layers of the non-active area may be formed of a same material as the plurality of banks in the active area.

The plurality of holes may extend to at least one layer disposed below the top layer of the plurality of organic insulating layers in the non-active area.

The display device may further comprise a flexible circuit board which may be disposed on the plurality of first pad electrodes and include a plurality of second pad electrodes electrically connected to the plurality of first pad electrodes, respectively, and a conductive adhesive member which may be disposed between the plurality of first pad electrodes and the flexible circuit board, wherein the conductive adhesive member may be disposed to be filled in the plurality of holes.

The conductive adhesive member may include a plurality of conductive balls and some of the plurality of conductive balls may be disposed in the plurality of holes.

The display device may further comprise a passivation layer disposed on the plurality of organic insulating layers in the non-active area.

The passivation layer may overlap at least a part of the plurality of first pad electrode and the plurality of holes.

The plurality of micro LEDs may include an anode electrode, a first semiconductor layer disposed on the anode electrode, an active layer disposed on the first semiconductor layer, a second semiconductor layer disposed on the active layer, and a cathode electrode disposed on the second semiconductor layer.

The display device may further comprise a first electrode which may be disposed below the plurality of micro LEDs to electrically connect the pixel driving circuit and the anode electrodes of the plurality of micro LEDs, and a solder pattern which may be disposed between the first electrode and the anode electrode, wherein the first electrode and the anode electrode may be electrically connected by eutectic bonding using the solder pattern.

A display device according to an another aspect of the present disclosure comprise a substrate including an active area and a pad area, a pixel driving circuit disposed on the substrate in the active area, a first insulating layer which is disposed on the pixel driving circuit in the active area and is disposed on the substrate in the pad area, a second insulating layer disposed on the first insulating layer in the active area and the pad area, a third insulating layer disposed on the second insulating layer in the active area and the pad area, a plurality of banks disposed on the third insulating layer in the active area, a plurality of micro LEDs disposed on the plurality of banks, a plurality of insulating patterns formed in the third insulating layer in the pad area, a plurality of first pad electrodes disposed on the plurality of insulating patterns in the pad area; and a plurality of opening areas formed by the plurality of insulating patterns between the plurality of first pad electrodes.

The opening area may expose at least a part of a top surface of the third insulating layer of the pad area.

The display device may further comprise a flexible circuit board which may be disposed on the plurality of first pad electrodes in the pad area and may include a plurality of second pad electrodes electrically connected to the plurality of first pad electrodes, respectively.

One end portion of the plurality of opening areas may extend to the active area and is adjacent to the active area more than one end portion of the plurality of second pad electrodes.

The display device may further comprise a conductive adhesive member which may be disposed between the plurality of first pad electrodes and the flexible circuit board and may include a plurality of conductive balls, wherein the conductive adhesive member may be filled in the plurality of opening areas and at least some of the plurality of conductive balls is disposed in the plurality of opening areas.

The display device may further comprise a passivation layer disposed on at least some of a plurality of conductive patterns, wherein the passivation layer may overlap at least a part of the plurality of opening areas.

Although the example embodiments of the present disclosure have been described in detail with reference to the accompanying drawings, the present disclosure is not limited thereto and may be embodied in many different forms without departing from the technical concept of the present disclosure. Therefore, the example embodiments of the present disclosure are provided for illustrative purposes only but not intended to limit the technical concept of the present disclosure. The scope of the technical concept of the present disclosure is not limited thereto. Therefore, it should be understood that the above-described example embodiments are illustrative in all aspects and do not limit the present disclosure. All the technical concepts in the equivalent scope of the present disclosure should be construed as falling within the scope of the present disclosure.

What is claimed is:

1. A display device, comprising:
a substrate including an active area and a non-active area;
a pixel driving circuit disposed on the substrate in the active area;
a plurality of micro light emitting diodes (LEDs) which is disposed on the pixel driving circuit in the active area and is electrically connected to the pixel driving circuit;
a plurality of organic insulating layers disposed on the substrate in each of the active area and the non-active area; and
a plurality of first pad electrodes disposed on the plurality of organic insulating layers in the non-active area,
wherein a total thickness of the plurality of organic insulating layers in an area overlapping the plurality of first pad electrodes is larger than a total thickness of the plurality of organic insulating layers in an area between the plurality of first pad electrodes.

2. The display device according to claim 1, wherein in the non-active area, a top layer, among the plurality of organic insulating layers, includes a plurality of holes disposed between the plurality of first pad electrodes.

3. The display device according to claim 2, wherein the plurality of holes exposes at least a part of a top surface of a layer disposed below the top layer of the plurality of organic insulating layers.

4. The display device according to claim 2, wherein at least one of the plurality of organic insulating layers extends between the pixel driving circuit and the plurality of micro LEDs in the active area.

5. The display device according to claim 1, wherein a top layer of the plurality of organic insulating layers in the active area and a top layer of the plurality of organic insulating layers in the non-active area are disposed on a same layer, and in the non-active area, the plurality of first pad electrode is in contact with the top layer of the plurality of organic insulating layers.

6. The display device of claim 5, wherein the top layer of the plurality of organic insulating layers in the non-active area and the top layer of the plurality of organic insulating layers in the active area are connected to each other and are formed of a same material.

7. The display device according to claim 1, further comprising:
a plurality of banks disposed between the plurality of organic insulating layers and the plurality of micro LEDs in the active area,
wherein a top layer of the plurality of organic insulating layers is disposed on a same layer as the plurality of banks in the non-active area, and the plurality of first pad electrodes is in contact with the top layer of the plurality of organic insulating layers.

8. The display device of claim 7, wherein the top layer of the plurality of organic insulating layers of the non-active area is formed of a same material as the plurality of banks in the active area.

9. The display device according to claim 2, wherein the plurality of holes extends to at least one layer disposed below the top layer of the plurality of organic insulating layers in the non-active area.

10. The display device according to claim 2, further comprising:
a flexible circuit board which is disposed on the plurality of first pad electrodes and includes a plurality of second pad electrodes electrically connected to the plurality of first pad electrodes, respectively; and
a conductive adhesive member which is disposed between the plurality of first pad electrodes and the flexible circuit board,
wherein the conductive adhesive member is disposed to be filled in the plurality of holes.

11. The display device according to claim 10, wherein the conductive adhesive member includes a plurality of conductive balls, and some of the plurality of conductive balls is disposed in the plurality of holes.

12. The display device according to claim 2, further comprising:
a passivation layer disposed on the plurality of organic insulating layers in the non-active area.

13. The display device of claim 12, wherein the passivation layer overlaps at least a part of the plurality of first pad electrodes and the plurality of holes.

14. The display device according to claim 1, wherein the plurality of micro LEDs includes:
an anode electrode;
a first semiconductor layer disposed on the anode electrode;
an active layer disposed on the first semiconductor layer;
a second semiconductor layer disposed on the active layer; and
a cathode electrode disposed on the second semiconductor layer.

15. The display device of claim 14, further comprising:
a first electrode which is disposed below the plurality of micro LEDs to electrically connect the pixel driving circuit and the anode electrodes of the plurality of micro LEDs; and
a solder pattern which is disposed between the first electrode and the anode electrode,
wherein the first electrode and the anode electrode are electrically connected by eutectic bonding using the solder pattern.

16. A display device, comprising:
a substrate including an active area and a pad area;
a pixel driving circuit disposed on the substrate in the active area;
a first insulating layer which is disposed on the pixel driving circuit in the active area and is disposed on the substrate in the pad area;
a second insulating layer disposed on the first insulating layer in the active area and the pad area;
a third insulating layer disposed on the second insulating layer in the active area and the pad area;
a plurality of banks disposed on the third insulating layer in the active area;
a plurality of micro light emitting diodes (LEDs) disposed on the plurality of banks;
a plurality of insulating patterns formed in the third insulating layer in the pad area;
a plurality of first pad electrodes disposed on the plurality of insulating patterns in the pad area; and
a plurality of opening areas formed by the plurality of insulating patterns between the plurality of first pad electrodes.

17. The display device of claim 16, wherein the plurality of opening areas exposes at least a part of a top surface of the second insulating layer of the pad area.

18. The display device of claim 16, further comprising:
a flexible circuit board which is disposed on the plurality of first pad electrodes in the pad area and includes a plurality of second pad electrodes electrically connected to the plurality of first pad electrodes, respectively.

19. The display device according to claim 18, further comprising:
a conductive adhesive member which is disposed between the plurality of first pad electrodes and the flexible circuit board and includes a plurality of conductive balls,
wherein the conductive adhesive member is filled in the plurality of opening areas, and at least some of the plurality of conductive balls is disposed in the plurality of opening areas.

20. The display device according to claim 16, further comprising:
a passivation layer disposed on at least some of a plurality of conductive patterns,
wherein the passivation layer overlaps at least a part of the plurality of opening areas.
